(19) United States
(12) Patent Application Publication
(10) Pub. No.: US 2014/0100839 A1
(43) Pub. Date: Apr. 10, 2014

(54) Method for controlling properties of simulated environments

(71) Applicant: David Joseph Arendash, Fremont, CA (US)

(72) Inventor: David Joseph Arendash, Fremont, CA (US)

(21) Appl. No.: 13/987,894

(22) Filed: Sep. 12, 2013

Related U.S. Application Data
(60) Provisional application No. 61/743,827, filed on Sep. 13, 2012.

(51) Int. Cl. G06F 17/50; H03G 3/20

(52) U.S. Cl. CPC G06F 17/5009; H03G 3/20
USPC 703/21; 700/94; 381/107; 381/98

(57) ABSTRACT

Computer implemented methods for the control of properties in computer simulations (such as video games) based on bitmaps are disclosed. In these methods, a bitmap is used as a reference file for an Audio Zone, and the bitmap values indicate properties within the virtual scene. To compute the value of a property (such as audio loudness), the bitmap is sampled at coordinates that correspond to the virtual location of the observer. Properties of the bitmap, such as the brightness associated with a pixel in the bitmap, may be designated to correspond the loudness of an associated sound.

Bitmap-based Audio Zones are intuitive to use for the scene designer. Programming code for accessing bitmaps is well known and robust, and can have a small computational footprint and reduced memory requirements. The method is therefore suitable for real-time simulations such as video games, and resource-limited devices such as hand-held computers or smartphones.

### CROSS-REFERENCE TO RELATED APPLICATIONS

This patent application claims the benefit of U.S. Provisional Patent Application No. 61/743,827, filed on Sep. 13, 2012, which is also incorporated herein by reference.

### FIELD OF THE INVENTION

This invention relates to the field of simulated environments for computer-implemented applications such as video games, virtual reality (VR), and computer-generated imagery (CGI) for motion pictures, television, and the Internet. It presents a method and a related system for designing and controlling properties and attributes in such simulated environments, and in particular, for audio signal synthesis, management, and presentation.

### BACKGROUND OF THE INVENTION

In simulated environments, such as those used in immersive computer applications such as video games and virtual reality, effects such as sound, lighting, shadows, and other characteristics of the virtual environment are often spatially dependent. Their presentation to a user, through video outputs for presentation on a screen, through audio outputs, such as audio speakers or through headphones, or through other output paths, such as tactile stimuli in VR gloves, depends upon the virtual coordinates of the sound or light source within the geometric confines of the simulated environment as well as on the virtual coordinates of the user.

A great deal of attention and innovation has been applied to modeling visual phenomena for games and virtual reality environments. Sources of light can be specified, and the luminous flux that would fall from a source of a particular size and shape onto a real world object of a different predefined size and shape can be calculated. Then, if a virtual model of the surface properties of the object is also present (specifying variables such as color, reflectance, surface texture, orientation, etc.), the amount of light scattered from the object in various directions can also be computed. Using these techniques, an image of the object at it would appear from a particular viewpoint when illuminated by the specified source or set of sources can be computed, and the results of the computation displayed on a screen or other display device. This process of image computation is often called “rendering”. [See, for example, A. Appel, “Some techniques for shading machine renderings of solids”, Proceedings of the Spring Joint Computer Conference, vol. 32, pp. 37-49 (1968); and M. Pharr and G. Humphreys, “Physically Based Rendering From Theory to Implementation” (Amsterdam: Elsevier/Morgan Kaufmann, 2004).]

Existing rendering systems often rely on complex physical modeling and/or complex mathematical computation and programming to simulate how an illuminated real-world object should appear. Because visual presentation is very information intensive, and the human eye is extremely sensitive to small anomalies in visual presentation, these computational rendering techniques are often very time consuming and, if used in a real-time display environment such as a video game, may require additional graphics processing capabilities to make the viewed image “believable.” One example of commonly used rendering software is Autodesk Maya software, produced by Autodesk Inc. of San Rafael, Calif. [for more on Maya, see <http://www.autodesk.com/products/autodesk-maya/overview> <http://en.wikipedia.org/wiki/Maya_(software)>].

The final result of a visual rendering may be stored and displayed as a simple electronic image file. One such image file is a “bitmap”.

Traditionally, a “bitmap” was a format for a binary image array, in which each element of the array is mapped to a single bit, either 0 or 1. The term “bitmap” has come to also be applied to the more general case of what is more technically called a “pixelmap”, in which each element of an array of picture elements (also called “pixels”) is mapped to one or more numeric values. For the purposes of this Application, the term “bitmap” should be interpreted to be the more general case of a “pixelmap”, which in some circumstances may also be a traditional bitmap.

The numeric values associated with each pixel may be associated with (but not limited to) the properties of color; transparency, hue, brightness, etc. The numeric values may be integers or real numbers, depending on the application for which it is intended.

FIGS. 1-4 illustrate various prior art examples of bitmaps.

Turning now to FIG. 1, FIG. 1A illustrates a table 110 representing the basic structure of a bitmap. The bitmap in FIG. 1A has any number of cells arranged in an array of columns and rows, indexed by the coordinates (u,v) 101. By convention, bitmaps are indexed with integers, starting with 0 (e.g. 0, 1, 2, 3, . . . , C−1 when there are a total of C columns, 0, 1, 2, 3, . . . , R−1 when there are a total of R rows). Each element of the array (i.e. each pixel), identified by ordinates (u,v), has associated with it a value, represented in FIG. 1 by the number placed with the cell. Turning now to FIG. 1B, when the bitmap is read for display as a picture or image 111, this numeric value is generally rendered to a computer display or printed medium to produce the corresponding pattern of bright or dark spots 115. For the illustration of FIG. 1, a value of 0 is rendered as black, and a value of 1 is rendered as white (bright) and values in between are given various shadings.

Turning now to FIG. 2, a variant of a bitmap is shown in which a “palette” of indices is employed. The palletized bitmap 120 in FIG. 2A again has any number of cells arranged in an array of columns and rows, indexed by the coordinates (u,v) 101. In this case, however, each pixel has associated with it an ID value. As illustrated in FIG. 2B, the ID value can be interpreted by referring to a palette 121. The palette holds the key relating a listing of ID values 122 to a number of values for various channels 123. In this example, three values respectively defusing values for red, green, and blue used to render the image are associated with each ID value. Note the number of values in each palette entry may be whatever is needed for the intended purpose, and are not limited to the three values used in this example. For purposes of this Application, a ‘palletized bitmap’ will be understood to mean a bitmap whose pixels consist of identifiers into a palette of attributes.

Turning now to FIG. 3, a variant of a bitmap called a “multi-planar bitmap” 130 is shown. The multi-planar bitmap 130 in FIG. 3 has a number of arrays of cells each arranged in an array of columns and rows, and each indexed by the coordinates (u,v) 101. In this variant, each array can be viewed as a plane, and, as illustrated here, each plane contains the same number of rows and columns. As typically used, three planes are used and the planes typically correspond to the red, green, and blue color portions of an image.

Turning now to FIG. 4, another variant of the bitmap is called the “tiled bitmap” is shown. First turning to FIG. 4A, an array of values 140 is divided into 4 sub-arrays, or tiles), where each tile represents a ‘slice’ of a 3-dimensional volume. Each tile can be viewed as its own 2-dimensional bitmap, and represents a slice of the depth (the w component of a (u,v,w) multi-planar array). Turning now to FIG. 4B, a rendering 141 of the four individual ‘slices’ is shown, with a numeric value of 0 rendered as white (blank), and a value of 1 rendered as black. Such displays are often used to present medical data, such as CAT scan and MRI imaging results, with each tile representing a slice through the body. FIG. 4C illustrates the four renderings of FIG. 4B combined in a 3-D representation, producing a 3-dimensional volumetric image 143 indexed with coordinates (u,v,w) 103.

The two coordinate axes of the arrays in bitmaps generally correspond to orthogonal axes in the rendered image, and often referred to as “(u,v)” 101 or “(u,v,w)” 103, where u represents the index of columns (width), v represents the index of rows (height), and w represents the index of tiles (depth). The (u,v,w) coordinates are often normalized to have a range of values [0,1] by the formulae:

u=c/(C−1)

v=r/(R−1)

w=t/(T−1)

where c is the column number (indexed 0, 1, 2, 3, . . . ), C is the width or total number of columns, r is the row number (indexed 0, 1, 2, 3, . . . ), R is the height or total number of rows, t is the tile number (indexed 0, 1, 2, 3, . . . ), and T is the depth, or number of tiles.

Several types of “bitmaps” are used as common electronic file formats to represent images. The most well known is the BMP bitmap format (file extension: .bmp) [see <http://en.wikipedia.org/wiki/BMP_file_format>]. For most purposes, standardized compressed bitmap files such as GIF, PNG, TIFF, and JPEG are used; lossless compression in particular provides the same information as a bitmap in a smaller file size [see, for example, J. Thomas & A. Jones, “Communicating Science Effectively: a practical handbook for integrating visual elements”, IWA Publishing. ISBN 1-84339-125-2 (2006)]. TIFF and JPEG have various options. TIFF is usually either uncompressed, or uses lossless Lempel-Ziv-Welch compression like GIF. JPEG is usually a lossy compression. PNG uses deflate lossless compression, another Lempel-Ziv variant [see J. Ziv & A. Lempel, “Compression of individual sequences via variable-rate coding”, IEEE Transactions on Information Theory, vol. 24(5), p. 530 (1978)].

Although there has been a great deal of effort put towards visual rendering for video display, audio “rendering” has generally been neglected. This may be because the computational requirements of the relatively low bandwidth audio signal have not been viewed as computationally challenging when compared to the video-processing problem. If one has the programming skills and talent to create a visual rendering from multiple light sources, creating an audio “rendering” for a scene with multiple sources of sound may seem like a trivial special case.

However, from a practical point of view, audio rendering (analogous to image rendering) can have its own difficulties. For the creation of soundtracks for animated movie features, although each frame of a film image may be rendered using hundreds or even thousands of hours of computer time, the audio signals are often still created manually in a sound studio by sound effects crew, also known as Foley artists, as they watch the generated animation projected on a screen. The Foley artist may, for example, clap coconuts together to make the sound of horses galloping, and as the horses move away, manually make the sound quieter in synchronization with the action taking place on screen.

The Foley artist is a practical solution for making movies because a human can better judge how a human would perceive the sounds present in the rendered moving image, and adapt appropriately. Several “takes” can be made to record the audio soundtrack, and the single best recording can be edited into the final version. However, for some simulated environments, for example, video games, it is obviously not possible to have a live Foley artist present to create the sounds. For such a situation, the computational approach may have to be employed.

Likewise, although audio rendering may be seem simple for one skilled in the art of image processing, many game designers are not image processing experts, and simply want to create a fun virtual environment. They can imagine an audio environment easily, but programming the commonly used tools to create audio environments is not trivial. [For more on the art of audio design for video games, see Alexander Brandon, “Audio Middleware—The Essential Link From Studio to Game Design”, AudioNext Magazine, (June 2007); V. Gal, C. Le Prado, J. B. Merrylands, S. Natkin, L. Vega “Processes and tools for sound design in computer games” Proceedings of International Computer Music (2003); and Axel Stockburger “The game environment from an auditive perspective” <http://audiogames.net/pics/upload/gameenvironment.htm>.]

‘Spatialization’ is the process of assigning a location to something. In the field of computer-simulated environments, spatialization is used for properties such as sound, light and shadow, physics, and programmatic control. The basic elements, components and interfaces for a computer-simulated environment, such as used for playing video games, is shown in FIG. 5. The ‘scene’ or ‘world’ is described using geometric constructs in the software modules 040, comprising the application layer 048 storing and executing the code for the video game, and a game system control layer 080 (these instructions can also be generated programmatically in the application layer 048, by reading software stored either within the system or read from a computer-readable medium (CRM) such as a flash drive 7075 or an optical disk 7076, or loaded from a network 7777 through a network interface 077). By the term ‘scene’, it will be understood to mean the data defining the geometry, lighting, sound, physics, and any other effects within the simulated environment, and that are stored in physical memory or on a non-transient computer readable medium. Data on how to render the ‘scene’ will be delivered via an internal bus or through a network to be running in the computer's CPU(s) and GPU(s).

Overall, the game system 010 also comprises hardware such as a processor 050, input/output (I/O) interfaces 070 that connect to external sources of data (e.g. drives for computer readable media 075, 076, interfaces to networks 077, and inputs from the player 001 through hardware such as a keyboard 073, mouse 072, or game controller 085, or other I/O devices such as VR gloves, IR connected remote controllers such as those manufactured for the Wii® game system by Nintendo Co. Ltd. of Kyoto, Japan, remote camera interfaces such as the Kinect® for Xbox 360® manufactured by Microsoft Corporation of Redmond, Wash. Other interface devices will be known to those skilled in the art.

The game system 010 will also comprise software modules that manage the data flow associated with the presentation of virtual environments to the human player 001. The application layer 048 implements specific logic for a given simulated environment (for example, the game rules) using the processor 050. The human player 001 provides input via devices such as a keyboard 073, a mouse 072 and/or through a handheld game controller 085 or the other devices mentioned above. The control layer 080 processes the geometry, lighting, sound, physics and possibly other data into an experience the human player 001 can perceive via a audio renderer 081 and audio reproduction hardware through an output channel 088 to, for example, speakers or headphones 089, and/or via a video renderer 091 to video display 099. The audio renderer 081 generally comprises a sound field model 083 and an audio signal processor 085. Pre-recorded audio signals 089 may also be provided to the audio signal processor 085 as a data stream, just as pre-recorded videos 099 may be provided to the video rendered 091.

Several techniques exist for the computation of an audio signal based on elements in a virtual environment. For example, if many sources of sounds are distributed within a simulated environment, each audio source is indicated by a location, as well as a range or area of effect, and a stored audio recording, which will be streamed through the audio output device and be heard by the user. This audio recording is not automatically occluded or filtered by the geometry in the scene. To do this, and therefore more realistically render the audio as it would be perceived by the user, prior art techniques such as proximity sensing [see, for example, Axel Stockburger “The game environment from an auditive perspective” <http://audiogames.net/pics/upload/gameenvironment.htm>], or acoustical modeling can be used. [For references on acoustical modeling, see for example, Foad Hamidi and Bill Kapralos, “A Review of Spatial Sound for Virtual Environments and Games with Graphics Processing Units”, The Open Virtual Reality Journal 1, 00-00, pp. 1-10 (2009); Dmitry N. Zotkin, Ramani Duraiswami, & Larry S. Davis, “Rendering Localized Spatial Audio in a Virtual Auditory Space”, University of Maryland, College Park, Md. (2002) <full text: citeseerx.ist.psu.edu>; and Oscar Pablo Di Liscia, “Sound spatialisation using Ambisonic” <http://wvvw.academia.edu/887707/Paper_tittle_Sound_spatialisation_using_Ambisonic_Topics_involved_-Physical_modeling_and_sound_diffusion-Digital_audio_processing>.]

In the case of prior art proximity-sensing techniques, the designer of the virtual scene must create volumetric regions and programmatically control indicated sounds as the user moves about the scene. This is illustrated in FIG. 6. In this particular case, a virtual source of a sound has a spherical area of effect (generally easy to model), which, as illustrated in cross section in FIG. 6A, appears as a circle 601 when viewed from above. As illustrated in FIG. 6B, if the area of the scene is not circular but, for example, a square 602, a perfect fit of the spherical sound 601 to the square scene 602 is not possible. There will be areas 606 where the sound is missing, and other regions 610 where the sound can be heard even though it should not be heard.

As illustrated in FIG. 6C, for an irregularly shaped space 612 such as a triangle, the problem of filling the space with audio sources providing uniform coverage can be complicated. The problem can be addressed by placing multiple instances of the effect 611 (e.g. sound sources) in a scene, in an attempt to cover the entire space 612. The multiple instances may be of differing sizes, as illustrated, but in most cases, there will never be a perfectly seamless fit. There will be virtual regions 626 in which there is still no sound. To minimize these regions 626, there may be regions 633 in which the effects 611 are allowed to overlap. However, in these overlapping regions 633, the audio effect may be doubled. The results may be highly undesirable (for example, a sudden doubling in sound volume when the virtual character enters the overlap region). Likewise, there may still be regions 627 in which sound can be heard when it should not be heard.

In the case of prior art acoustical modeling techniques, the designer of the virtual scene must place acoustic parameters indicating coordinates in the scene where sound is occluded, reflected, filtered, etc., and then create software code to apply algorithms that model the sound pattern. FIG. 7 shows a simple scene where there are two small rooms in the scene, partially separated by a short wall 710. The partial separation leaves an opening 709 between the two rooms, which passes sound unobstructed. The wall 710 may only partially occlude the sound, and/or may provide filtering (such as only passing the low-frequency components of the sound).

In the left hand room, a sound source 700 (indicated by an S) radiates virtual sounds, and in the right hand room, a listener 701 (indicated by an L) will detect the sound. In this example, the listener will also function as an audio observer component. For the purpose of this Application, the term ‘listener’ will be understood to mean the aspect of a virtual observer which samples audio from the observer's current position in the scene, i.e. a virtual microphone, or virtual ears. The term ‘observer’ will be used as a generic term for a virtual point of view, and may or may not correspond to the position of the virtual character in the game, depending on how the game has been designed, or may or may not correspond to the position of a listener, which is always a “virtual microphone”.

In the acoustical modeling technique, ray-tracing calculations are employed to determine paths that a sound will take in order to account for filtering, echoes, and other acoustical effects. For example, rays 711 indicating sound emitted by the virtual source 700 and propagating directly to the wall 710 will be attenuated by the wall 710 as they pass into the right hand room, whereas rays 721 indicating sound emitted by the virtual source 700 that bounce off the other walls and pass through the opening 709 will not be attenuated.

Performing these calculations in real-time is expensive computationally, and especially on limited hardware resources such as hand-held devices, at best only a crude approximation to the audio effects can be made,

These approaches have limitations. Using proximity sensing, the designer is limited to simple shapes of audio sources, usually just ellipsoid or spherical. To get arbitrary shapes, the designer must use a large number of them and try arranging them into shapes that may never really approach the exact shape they need. The designer may spend a lot of time trying to approximate the area. Using acoustical modeling, the software tools tend to be expensive, and the algorithms are extremely CPU-intensive, making this a less viable choice for real-time simulations, especially where hardware resources are very limited (such as hand-held devices). The geometry must also be designated to have certain acoustic properties, typically a time-consuming task for designers.

There is therefore a need to have a solution to audio design for simulated environments that is easy and intuitive for the scene designer to use, and has a fast computation time for running real-time simulations.

### BRIEF SUMMARY OF THE INVENTION

The invention disclosed with this Application is a method that is simple to implement for the game scene designer, while providing the potential for a rich and complex virtual audio environment. This achieves this goal by using a reference file, such as a bitmap, to direct the presentation of audio signals. As typically used, once this invention is implemented in the simulated environment, very little, or in some cases, no additional programming is needed to manage the audio environment. Bitmaps are easily generated by a number of graphics and drawing programs, and so the entire audio spatialization and interaction task can be accomplished using a visual design approach.

In some embodiments, a bitmap is used by the scene designer to provide this reference file, representing the audio instructions as a visual map, indicating audio zones in a scene where the audio has certain properties (such as loudness, also commonly called “volume”). Such bitmaps may be produced by an artist's hand, through image capture (e.g. photography, scanning, etc.), via an algorithm, or by any other means for generating graphics and image files known to those skilled in the art. They are intuitive for the scene designer to use, as it can look very much like a map.

Audio management for virtual environments using reference files to define Audio Zones may be implemented easily, compactly, and quickly. They are efficient in that they have a small memory footprint and fast computation, making them ideal for real-time simulations such as video games, and resource-limited devices such as hand-held devices.

### BRIEF DESCRIPTION OF THE DRAWINGS

FIG. 1A illustrates the typical structure of a prior art bitmap.

FIG. 1B illustrates a rendered image corresponding to the prior art bitmap of FIG. 1A.

FIG. 2A illustrates the structure of a prior art palletized bitmap.

FIG. 2B illustrates a palette corresponding to the prior art bitmap of FIG. 2A.

FIG. 3 illustrates the structure of a prior art multi-planar bitmap.

FIG. 4A illustrates the structure of a prior art tiled bitmap.

FIG. 4B illustrates a set of 2-D rendered images corresponding to the prior art tiled bitmap of FIG. 4A.

FIG. 4C illustrates a 3-D image representing a combined rendering of the prior art tiled bitmap of FIG. 4A.

FIG. 5 presents a block diagram of the basic components and interface for a prior art computer-simulated environment, such as one used for playing video games.

FIG. 6A illustrates a cross-section of a spherical virtual sound source as used in prior art proximity-sensing techniques for audio computation.

FIG. 6B illustrates the overlap of a non-circular scene and the virtual sound source of FIG. 6A when used with prior art proximity-sensing techniques for audio computation.

FIG. 6C illustrates the overlap of a triangular shaped space and multiple instances of the virtual sound source of FIG. 6A when used with prior art proximity-sensing techniques for audio computation.

FIG. 7 illustrates a prior art acoustical modeling technique for audio computation.

FIG. 8 presents a flow chart of the operation of an audio rendering engine according to the invention.

FIG. 9 presents a flow chart of the operation of an Audio Zone code portion of an audio rendering engine according to the invention.

FIG. 10 presents a flow chart of the operation of an audio signal processor portion of an audio rendering engine according to the invention.

FIG. 11A illustrates the projection of a virtual listener onto an Audio Map according to the invention.

FIG. 11B illustrates an example of a key for mapping the shading assignments for the Audio Map of FIG. 11A.

FIG. 12 illustrates the projection of a virtual listener onto two Audio Maps according to the invention.

FIG. 13 illustrates the projection of a virtual listener onto a rotated Audio Map according to the invention.

FIG. 14A illustrates the numeric values for an Audio Map according to the invention.

FIG. 14B illustrates the calculation of gradients for the Audio Map shown in FIG. 14A according to the invention.

FIG. 15 illustrates managing multiple audio data streams using multiple Audio Zones according to the invention.

FIG. 16 illustrates an example of a set of Audio Maps according to the invention, in which several planar maps are stacked.

FIG. 17 illustrates an example of a set of Audio Maps according to the invention, in which four maps are placed in a “box” configuration.

FIG. 18 illustrates an example of a set of Audio Maps according to the invention, in which two maps are placed perpendicular to each other.

FIG. 19 illustrates an example of a set of Audio Maps according to the invention, in which several maps are placed in a radial arrangement.

FIG. 20 illustrates an example of an Audio Map according to the invention, in which the Audio Map covers a spherical parametric three-dimensional zone object.

FIG. 21 illustrates an example of a virtual scene from a simulated environment.

FIG. 22 illustrates the locations of audio planes for the Audio Maps according to the invention for the simulated environment of FIG. 21.

FIG. 23 illustrates an audio bitmap representing the intensity of zombie groans corresponding to the horizontal plane in FIG. 22 for the example of FIG. 21 according to the invention.

FIG. 24 illustrates an audio bitmap representing the intensity of zombie groans corresponding to the vertical plane in FIG. 22 for the example of FIG. 21 according to the invention.

FIG. 25 illustrates an audio bitmap representing the intensity of the audio stream from the virtual radio corresponding to the horizontal plane in FIG. 22 for the example of FIG. 21 according to the invention.

FIG. 26 illustrates a bitmap comprising a spiral formed using a prior art graphic program.

FIG. 27 illustrates a complex implementation of the bitmap of FIG. 26 used as an Audio Map according to the invention.

FIG. 28 illustrates the components for a computer that can be used in the implementation of the invention.

FIG. 29 presents a flowchart for an embodiment of the invention corresponding to the code listing presented in Appendix A.

FIG. 30 presents a flowchart for an embodiment of the invention corresponding to the code listing presented in Appendix B.

### DETAILED DESCRIPTIONS OF EMBODIMENTS OF THE INVENTION

### I. Preferred Embodiments

Methods and systems for spatialized control of properties based on bitmap sampling are described. In the following description, for purposes of explanation, numerous specific details are set forth in order to provide a thorough understanding of several embodiments of the invention. It will be apparent, however, to one skilled in the art that the invention can be practiced with or without these specific details.

The embodiments of the invention presented in this Application are mainly concerned with the management of audio information in virtual environments, such as whether to play a particular recorded soundtrack and how loud the audio volume should be. However, the properties that can be managed through the reference files as described in these embodiments are not limited to audio information alone, but may be applied to the management of any output channel presented to a user of a system that uses a simulated environment. These can include modifications to the visual display, tactile sensations, even olfactory and gustatory stimuli, should a system be provided with a means to output such signals. Likewise, the reference file as described in these embodiments is typically a bitmap, but other types of files may also be used according to the invention.

Although these examples of embodiments of the invention are presented in the context of playing video games in virtual environments, other systems that use virtual environments may apply embodiments of the invention as well. For example, in a surgical suite in a hospital, as a doctor moves surgical tools into an incision in a patient, sensors on the tools may provide input into a virtual environment based, for example, on remote imaging, such as an MRI scan, of that same patient. If the surgeon moves too close to delicate tissue, auditory feedback may be provided to the surgeon to warn of the possible danger. The warning might also be tactile, as in a vibration, or force-feedback in the case of robotic manipulators. The warning cues may be based on a simple bitmap provided by the output of typical MRI scanners. This may have application in situations where the surgeon cannot see exactly where his tools are being placed, but where sensors (for example, RFID sensors) can identify their position in space and be calibrated to the stored bitmaps of the patient's internal structures.

As described above, bitmaps are arrays of integer or real numbers that correspond to a property, typically of an image (e.g. color, brightness, transparency, etc.). In some embodiments of the present invention, an audio property (such as the loudness of a sound at a given location) can be represented by the numeric value or values associated with a pixel of the bitmap. The bitmap is sampled at an array location that corresponds to the location of the listener within the scene. Thus, a bitmap that may traditionally associate a pixel with image brightness (for example) is interpreted as simply having a numeric value, and that value can instead be used as the loudness of an associated sound.

In one embodiment, the system designer will produce a bitmap. The term “system designer” may be a programmer that is creating the entire virtual environment, or an artist tasked with creating specific aspects of certain scenes within the virtual environment, or some other person tasked with the creation of all or parts of the virtual environment. The bitmap may be created using a computer program such as Photoshop or Illustrator, produced by Adobe Systems of San Jose, Calif., originally designed for artists and graphic designers.

This bitmap is designated to correspond to predetermined planar geometric coordinates within a designated scene within a game setting, and arranged as any other 3D data object is arranged using the design tool framework. Thus this planar geometry has the bitmap rendered upon it, and the designer uses the design tool to move, size, and rotate the data object such that the bitmap aligns with the scene in a 1:1 correspondence.

The scenes in the virtual environments can be designated as “Audio Zones”. For purposes of this Application, an “Audio Zone” will be understood to mean a combination of an Audio Map (e.g. the bitmap), a zone object, and various associated Audio Transfer Functions that derive an aspect of audio rendering from a position in scene. The Audio Zone may be linked to one or more audio streams, either various means for synthesizing audio streams, or to prerecorded audio files.

A data structure that defines the Audio Zone will typically have a datum, which references the bitmap (or bitmaps, if more than one are used). This may be in the form of a textual reference (e.g. a name, tag, or other character string), a numeric reference (such as a unique identifying number), a reference to the memory location containing the bitmap(s), or any other common means of referencing data known to those skilled in the programming field. The scene designer may perceive these as options in the user interface of the design tool as a list of available audio streams, menu items, palette, or any other method of choosing items.

The Audio Zone may also reference a corresponding predetermined set of audio streams. This may be in the form of a textual reference (name, tag, or other character string), a numeric reference (such as a unique identifying number), a reference to the memory containing the bitmap(s), or any other common means of referencing data known to those skilled in the programming field. The loudness of this or these audio streams, as presented to the user, will change, depending on the relative position of the virtual character within the scene. The scene designer may perceive these as options in the user interface of the design tool as a list, menu, palette, or any other method of choosing items.

The Audio Zone may also contain data that may be set by the system designer that designates a property, such as a sound's loudness, to the numeric value of the bitmap. The data may be set via textual reference, numeric identifier, enumeration, or any other common means of referencing data known to those skilled in the programming field. The scene designer may perceive these as options in the user interface of the design tool, for example, as a drop-down menu item, which allows him to choose between, for example, loudness, pitch, echo, etc. The “brightness” of a pixel in the bitmap will then correspond to the loudness of the sound in a function designated by the user (for example, linear correspondence such that ‘dark’ is ‘quiet’ and ‘bright’ is loud′).

A scene may have one Audio Zone, or may be placed in several overlapping Audio Zones. For purposes of this Application, the term “Audio Meta-Zone” will be understood to mean a collection of two or more Audio Zones that may be combined mathematically.

In operation, the system user (typically a player of the game defining the virtual environment) controls a character that moves about within the virtual environment. When the character's virtual coordinates are within the bounds of a particular scene governed by the bitmap, the bitmap is sampled at a pixel location corresponding to the character's location in the scene. In some embodiments, bilinear interpolation may be performed to smooth values between pixels, and the resulting value (or interpolated value) is applied to the audio rendering portion of the simulation program to set the loudness or volume of the audio track designated to be controlled with this bitmap. [For more on interpolation methods, see <http://en.wikipedia.org/wiki/Interpolation>.]

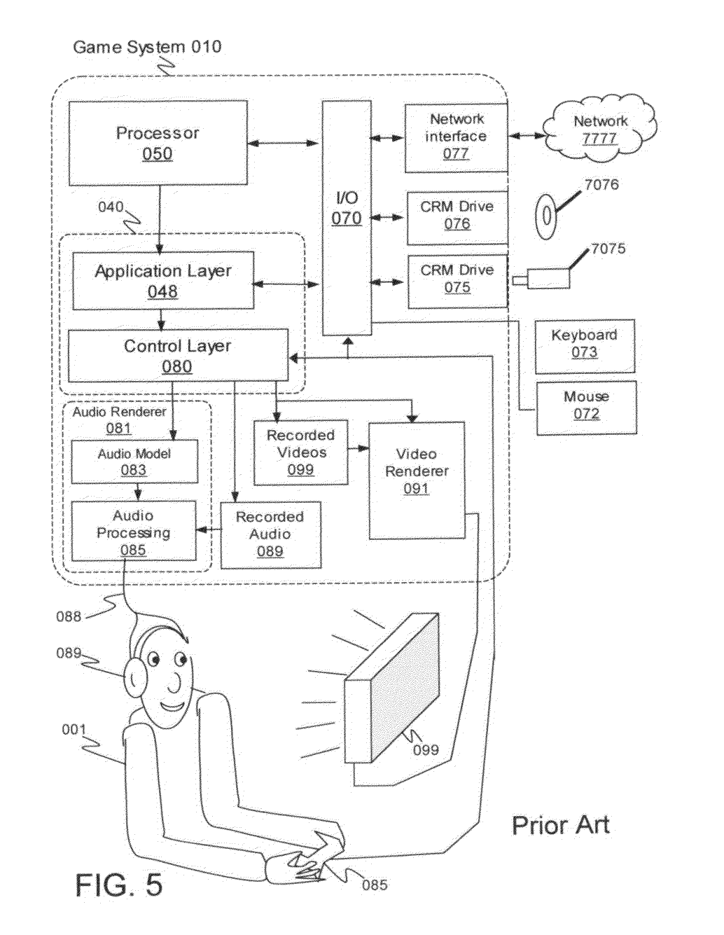

In the illustration of FIG. 5, the prior art system comprises an audio renderer 081, which in turn comprises an audio model 083 and an audio processing unit 085 that take prerecorded sound effects or soundtracks 089 and play them as needed according to the instructions of the computer game code.

In some embodiments of the present invention, the audio model 083 is now replaced with one or more bitmaps, and comprises associated software to access the bitmaps according to the invention.

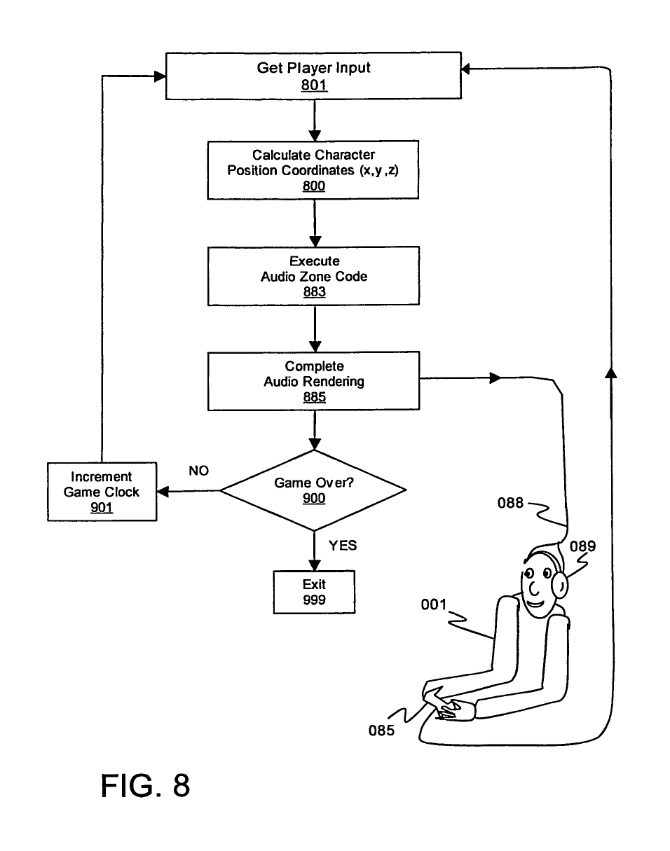

In some embodiments, the process of using a bitmap to govern an audio property (such as controlling the loudness of a sound) is accomplished in manner illustrated in FIGS. 8, 9 and 10.

FIG. 8 illustrates the overall flow of actions managing the audio renderer according to the invention (replacing the renderer 081 in FIG. 5). It is anticipated that the software running this loop will typically be operational the entire time that the virtual environment is active and the game is in progress.

In the initial step 801 of a clock cycle, the immediate input provided by a player 001 from a controller 085 or other input device is read by the system. The input may, for example, instruct the virtual character to move into a particular scene in the game.

In the next step 800, the revised virtual coordinates (x,y,z) of the listener (in this example, corresponding to the player's virtual character) are calculated.

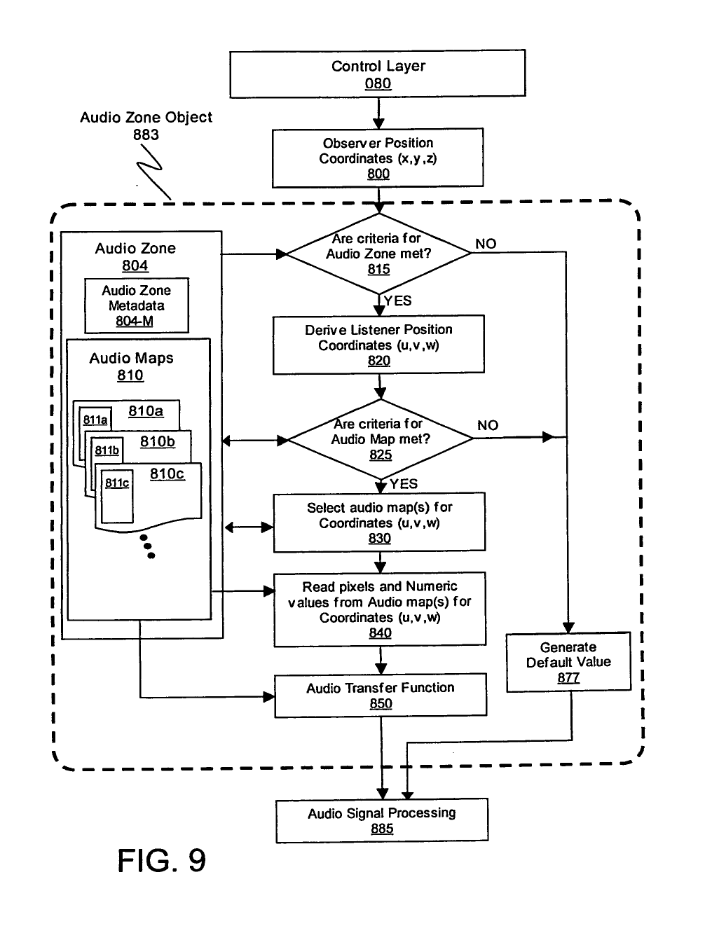

In the next step, the Audio Zone code 883 is executed to provide instructions for audio rendering. This step is shown in more detail in FIG. 9, and replaces the step shown as 083 in FIG. 5.

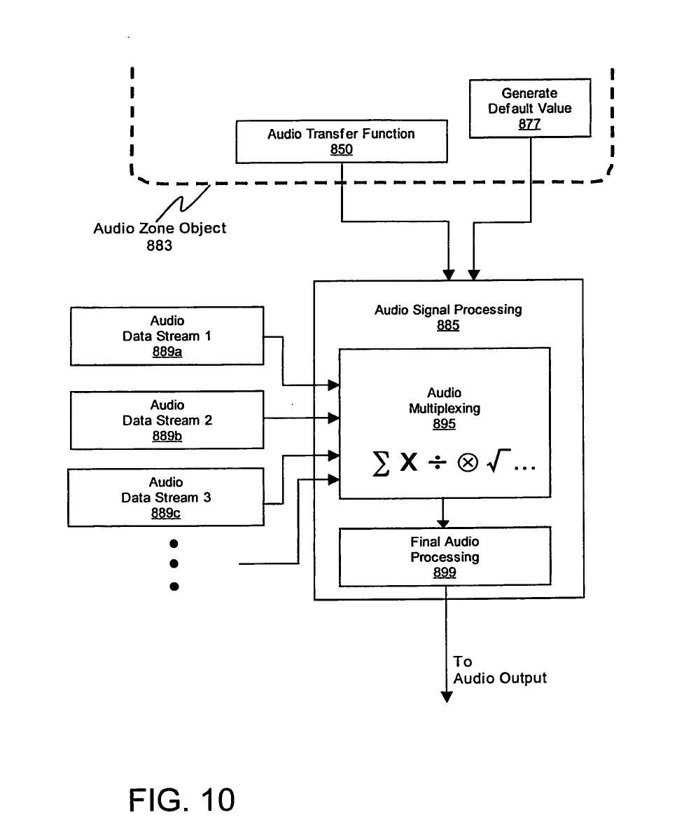

After the audio signal has been derived, in the next step 885, the audio rendering is completed by computing the actual signal needed to drive the audio output 088. This step is shown in more detail in FIG. 10, and replaces the step shown as 085 in FIG. 5.

In the next step 900, a check is made as to whether the game is actually now over. If the game is over, the procedure ends with an exit step 999. If the game is not over, in the next step 901, the clock is incremented, and the process begins again at the initial step 801, with signals generated by the user 001 monitored and incorporated into the virtual environment.

Turning now to FIG. 9, the steps generating the instructions for the generation of the audio signal (i.e. instructions for the Audio Transfer Function) are presented according to the invention

The entire process, designated as an Audio Zone object 883 (or Audio Zone code), is implemented as computer code (e.g. instructions on a machine readable medium that can be executed by a computer or other data processing system) and can be interpreted in some embodiments as being a substitute for all or portions of the audio model 083 of FIG. 5.

It should also be noted that, while the user of such a system may be designated a “player”, many games involve having the player control a character, either seen from outside (for example, in role-playing using 3rd-person perspective) or from the point of view of the character (often called “first-person shooter” games) through a virtual environment. The virtual character as controlled by the player may have certain coordinate designations, but beyond that, the character may have a designated portion of its anatomy (ears if using a humanoid character) that detects sound, and the virtual location of the sound detector may be distinct from the general position coordinates of the character. The location of this “virtual microphone” will be designated the position of the “listener”, while a generic point of view will be designated as corresponding to an “observer”. For purposes of this Application, “observer” (or an Observer Object) will be understood to mean the object in the scene that receives, samples, or observes the properties. For example (but not limited to): a character, a virtual microphone in a scene, a virtual camera in the scene, a material surface which receives lights or shadows, an computer-controlled character which receives moods or commands, etc. can all be “observers”. However, only a virtual microphone (or virtual ears) may be a “listener”.

The Audio Zone code 883 will comprise a collection of data 804 about the Audio Zone, with information such as boundaries, attributes to be controlled (e.g. audio, video, or other outputs), and also comprise metadata 804-M about the Audio Zone. The Audio Zone 804 may also comprise one or more Audio Maps 810a, 810b, 810c, . . . , each of which will be designated to provide audio guidance for a particular scene or portion of a scene in the game. In general, the Audio Zone will comprise metadata 811a, 811b, 811c, . . . associated with each Audio Map 810a, 810b, 810c, . . . . The metadata may be independent of the Map, or in some embodiments the Audio Map 810a, 810b, 810c, . . . will also comprise the metadata 811a, 811b, 811c, . . . . This metadata 811a, 811b, 811c, . . . may provide coordinate designations for which each map is to be used, and other information about the Audio Map and its usage conventions.

For purposes of this Application, the terms “Audio Map” or “Audio Zone Map” will be understood to mean a reference file such as a bitmap depicting a distribution, field, layout, schematic, or map, and comprising data corresponding to a property to be affected.

In the first step 800, as in FIG. 8, the listener's virtual position, or coordinates (x,y,z) in the scene is provided by the control layer 080 to the Audio Zone code 883. For the purposes of this Application, x will be understood to mean a spatial axis representing width, longitude, across, left-right direction, etc., while y will be understood to mean a spatial axis representing height, altitude, up-down direction, etc. and z will be understood to mean a spatial axis representing depth, latitude, back-front direction, etc. For the purpose of this Application, “coordinate system” will be understood to mean any multi-dimensional axis system, including but not limited to Euclidean or Cartesian coordinates, (x,y,z) coordinates, (u,v,w) coordinates, polar coordinates, cylindrical coordinates, spherical coordinates, etc. which are used for locating a point in multi-dimensional space.

In the next step 815, a comparison is made to determine if the listener's virtual position is within the axis-aligned bounding box of the Audio Zone 804. This is done by comparing the character's virtual (x,y,z) coordinates to the coordinates in the metadata 804-M defining the bounds of the Audio Zone. If the listener is out of the Audio Zone bounds, a NO result occurs, and the program code proceeds to the step 877 of assigning a default value (typically equal to zero) for the audio signal, and this default value is then passed to the audio signal processor 885.

However, if the coordinates of the virtual listener are within the corresponding coordinates defined by metadata 804-M for the Audio Zone, a YES result occurs, and the program code proceeds to the next step 820.

In this step 820, the coordinates of the listener (or character) are generated, generally by translation from the (x,y) coordinates of the game to the (u,v) coordinates of the Audio Zone.

In the next step 825, the actual bounds for the Audio Maps in the Audio Zone are accessed, and the Audio Maps relevant to the character's position are determined. If the character is out of bounds for all Audio Maps within the Audio Zone, a NO result occurs, and the program code proceeds to the step 877 of assigning a default value (typically equal to zero) for the audio signal, and this default value is then passed to the audio signal processor 885.

If, however, one or more Audio Maps are found to be relevant to the listener's position, the next step 830 identifies the relevant Audio Maps. Once those Maps are identified, the next step 840 identifies the pixels within the relevant Maps that are needed for computation of the audio stream. The Audio Zone Map coordinates may be rotated, scaled, skewed, or otherwise distorted relative to the listener's coordinates, so this step may comprise some additional coordinate transformations. In one embodiment of the invention, a convention is that the local (u,v) bounds of a bitmap are within [−0.5, +0.5]. Another convention may have the bitmap bounds within [0,1].

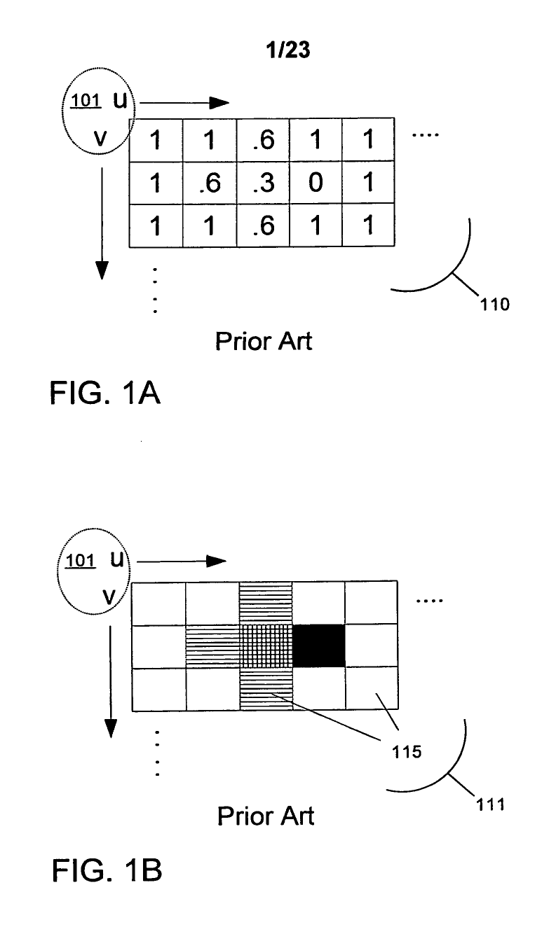

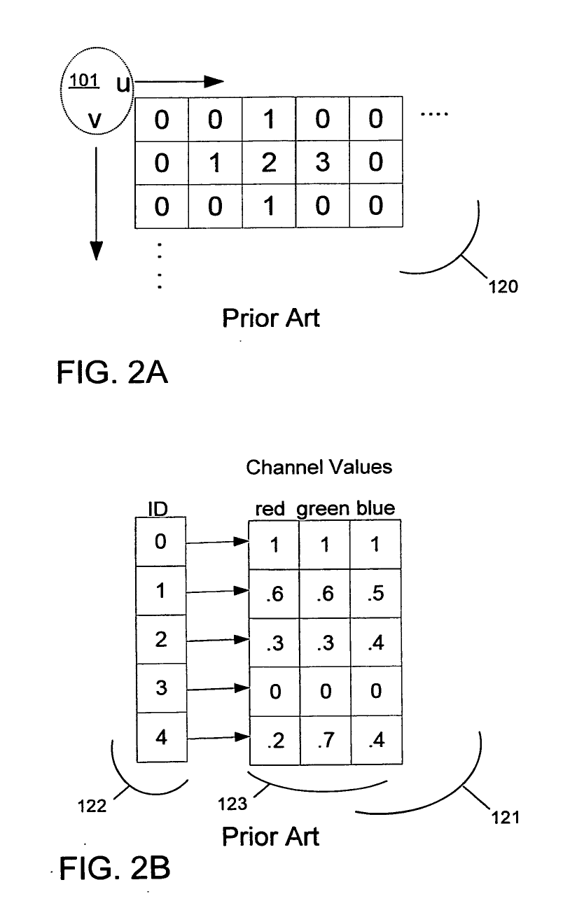

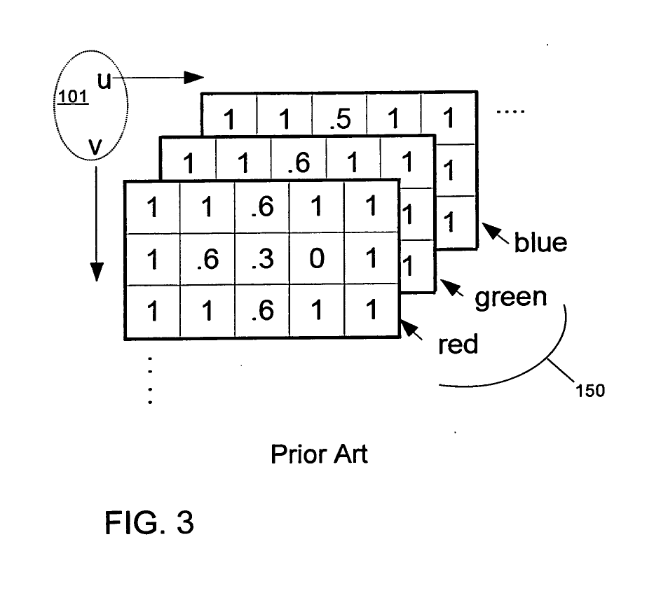

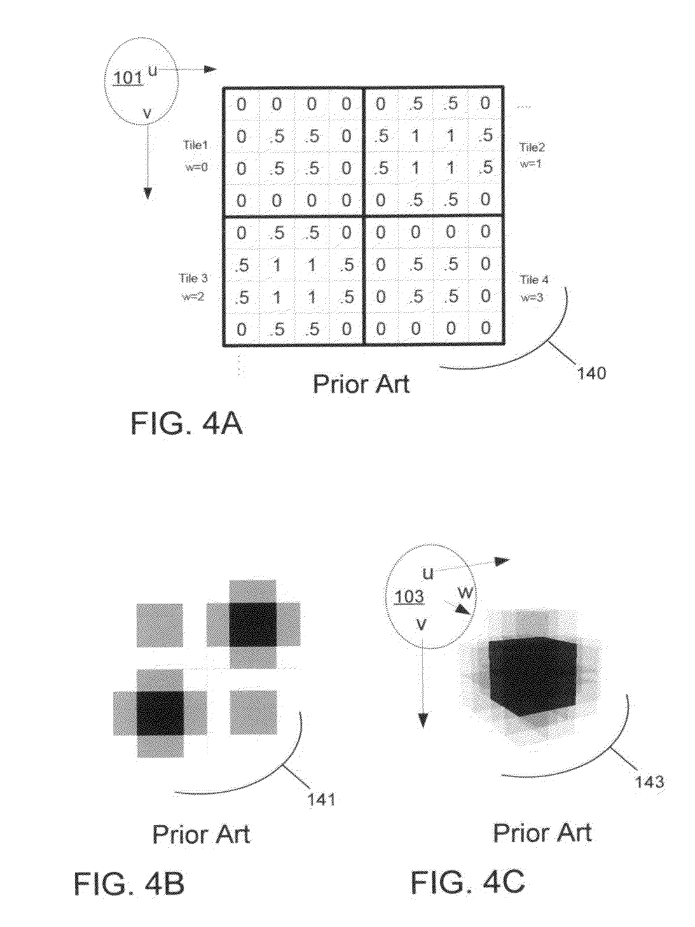

The actual implementation of this step will be dependent upon the programming environment used by the game designer. It may be as simple as a call to a framework-provided function such as, for example, the GetPixel(u,v) command in the Unity game engine API [for a description of the GetPixel function, see <http://docs.unity3d.com/Documentation/ScriptReference/Texture2D.GetPixel.html>]. It may involve accessing the storage unit containing the numeric array directly. The (u,v,w) coordinates generally correspond to the index of the pixel in the array structure defining the bitmap. The pixel may comprise a single numeric value (as was shown in FIG. 1), an ID number referring to a palette of values (as was shown in FIG. 2), set of numeric values (as was shown in FIG. 3), or a set of tiles (as was shown in FIG. 4).

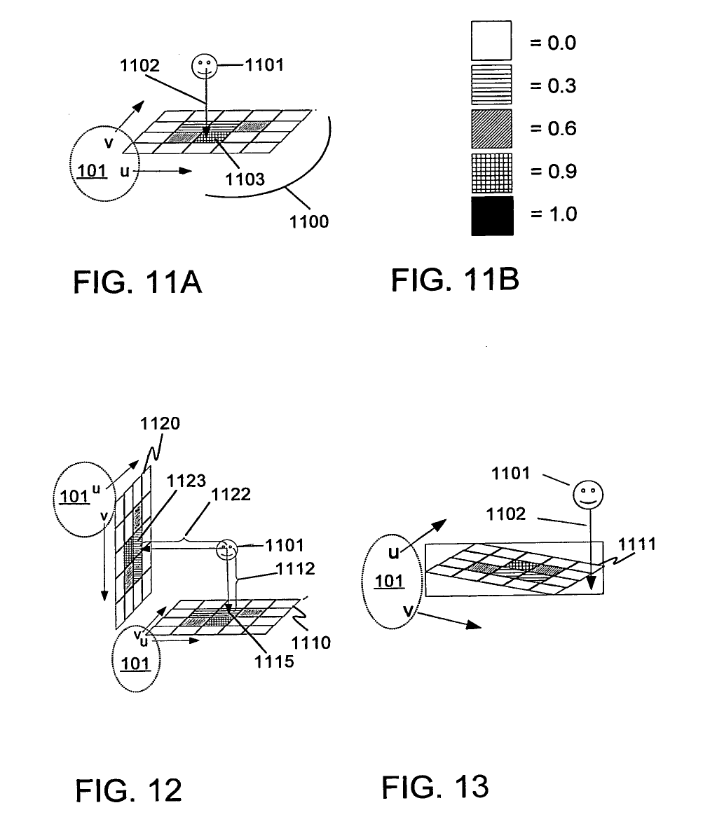

In the next step 850, the various pixels and pixel values from the Audio Map determined to be relevant are used to compute the actual behavior of the audio stream. More information will be provided on the possible mathematical operations used to compute this Audio Transfer Function in the discussion of FIG. 11.

For purposes of this Application, the term “Audio Transfer Function” will be understood to mean a mathematical and/or logical function which transforms part of an Audio Map to a quantifiable aspect of rendering sound (such as, but not limited to: loudness (volume), echo, reverberation, delay, phase, filtering profiles, such as low pass filters and high pass filters, distortion, pitch, noise addition, noise level, noise reduction, Doppler amount, amplitude modulation, frequency modulation, phase modulation, panning (i.e. the balance between left/right ears), spread (distribution among the various speakers in a multi-speaker system like Dolby 7.1), etc.)

The Audio Transfer Function applies the numeric value read from the one or more Audio Maps 810 to the code with functions that designate the action to be taken (e.g. a setting for the loudness of a synthesized sound or for playing a prerecorded audio track). If the listener's virtual coordinates are found to correspond to more than one Audio Map, a pixel is read for each Audio Map, and this step 850 may determine numeric values for the audio signal by a weighted interpolation function. The instructions generated by the code are then presented to the audio signal processor 885. It should be noted that, in some circumstances, the Audio Transfer Function may be a complex mathematical operation, while, in other circumstances, the Audio Transfer Function may be a simple unity function, i.e. multiplication by 1.

The audio signal processor 885, which is analogous to the prior art signal processor 085 shown in FIG. 5, now uses these instructions to manage the presentation of various audio streams 889, comprising sound effects and prerecorded tracks, similar to the prerecorded audio 089 of FIG. 5.

Turning now to FIG. 10, these audio streams (889a, 889b, 889c, . . . ) can be multiplied, mixed, attenuated, tuned, filtered, etc. according to the instructions generated in the Audio Transfer Function 850 with input from the numeric values read from the bitmaps stored as Audio Zone Maps 810a, 810b, 810c, . . . .

The relationship may be expressed in the following manner:

R_{F}=F(P)+F₁(A₀,A₁,A₂, . . . )

where R_{F} is the resulting value of the Audio Transfer Function in use (for example: loudness, but can be many things including echo, filtering, mass, strength, etc.), F is the Audio Transfer Function which maps the pixel value P to R_{F} (P), and P is the value of the pixel corresponding to the Observer Object. F₁ and its arguments A₀, A₁, A₂, . . . are optional arguments to the function which may take any other factors in the game into account (for example, a character that has just experienced an explosion in the game may experience temporary deafness; this will be an additional time-dependent factor affecting the Audio Transfer Function not related to any values in any Audio Map).

Retrieval of the pixel and its associated value may be represented by:

P=I(u,v,w,t)

where I is the bitmap (array of pixels) that are indexed by u and v (horizontal and vertical dimension), w depth (or tile), and t (time, in the case of dynamic (animated) bitmaps). Note also the coordinate transformation

(u,v,w)=G(x,y,z)

where G is the function that maps the Observer Object's location (x,y,z) (e.g. ‘world space’ but in any case a space common to both the Observer Object and the Zone Object comprising the Audio Map) to the bitmap space (u,v,w). Note that the values of u and/or v may result in numbers outside the range of the bitmap itself (i.e. less than zero or greater than one, or greater than the pixel dimension, etc.). Such ‘out of bounds’ values may be used to define the value R as zero or some other default constant, or be used to interpolate or extrapolate values between other Audio Zones.

The function F may be any mathematical function that suits the purpose of transformation from pixel value to property value, and may include (but will not be limited to):

F(P)=P [Identity function]

F(P)=1−P [Inversion function]

F(P)=Σ(Pr,Pg,Pb) [Sum function]

F(P)=log(P) [Logarithm function]

Note that if the Audio Map 810 uses a bitmap format that contains multiple channels, as are used in an RGBA bitmap (e.g. red, green, blue, alpha, etc.) as was illustrated in FIGS. 1-4, several properties may be controlled with the same bitmap. An example use of this might be red denoting loudness and green denoting echo, while blue denotes a low-pass filter value (for muffling sound), and alpha denoting which sound clip shall be heard (from a list of available sounds). Any number of channels may exist in the bitmap. Any bit depth may be represented in those channels. Those values may be integer or floating-point values. For the purposes of this Application, “channel” in the context of a bitmap will be understood to mean a numeric value or set of values corresponding to a property of a bitmap, for example, the red, green, blue, components of the colors of a pixel, the transparency of a pixel, etc.

The pixel value R_{F} may be more than a single number. If the bitmap contains a monochrome or palletized bitmap, it will be a single number.

In the case of a palletized bitmap, that number will be an index into an array of, for example, colors. Each color, or ranges of colors, may correspond to different audio or other properties.

Whether palletized or multi-channel, the colors of a bitmap may themselves each represent a unique property. A 256-color bitmap could then have up to 256 different properties represented within it, a 32-bit bitmap may have up to 4,294,967,296 unique properties, and so on. In some embodiments, ranges of colors or values may be defined (by the Audio Transfer Function) to correspond to different types of properties, and these may be combined in any way. For example, shades of green might indicate an area where a virtual character may roam, where different brightnesses of the green color indicates speed, but a pure black color means ‘stop here’.

Returning again to FIG. 10, the Audio Transfer function 850 provides instructions to the next step 885 for managing various audio signals. Several available audio data streams 889a, 889b, 889c are illustrated as providing input to the Audio Signal Processing step 885. The Audio Transfer Function is employed as a selector switch for which audio stream to send to the audio signal processor, and which functions should be applied to amplifying, attenuating, or mixing the streams. Once the processing instructions have been executed, the final step 899 is the final audio processing and the export of the signal to the audio channel 088.

Whether palletized or multi-channel, in some embodiments data normally representing colors in a bitmap may be processed by the Audio Transfer Function into different values (for example, representations of color), which then correspond to different properties. For example, the Hue of a bitmap might indicate a type of property (say, low-, middle-, or high-pass filtering), the Brightness the amount of filtering, and the Saturation the amount of echo. Other assignments of standard bitmap formats for various properties can be made by game designers skilled in the art.

FIGS. 11-13 illustrate several examples of interpreting values for audio properties from stored reference files, such as bitmaps.

FIG. 11A illustrates the mapping of the position of a virtual observer 1101 or listener using an Audio Map 1100, with standard pixel coordinates (u,v) 101. For this example, assume that the property is ‘the loudness (or volume) of a sound’. The more shaded pixels will denote the loudest regions, white will denote the silent regions, and medium shading will denote the audio volumes in between. FIG. 11B shows a key to mapping these shading assignments to numeric values, where 0 is white and 1 is black, and values in between 0 and 1 are shades of gray.

Returning to FIG. 11A, the position of the observer 1101 is projected onto the Audio Map bitmap at position 1102. Where this projected line intersects bitmap 1100 will (if the line is within the bounds of this bitmap) be the observer's nearest pixel 1103. The numeric value of pixel 1103 is then passed along to the audio transfer function.

FIG. 12 illustrates the mapping of the observer's virtual position 1101 onto two Audio Maps 1110 and 1120. For this example, let us say that the property is ‘the loudness (or volume) of a sound’. The more shaded pixels will denote the loudest regions, white will denote the silent regions, and medium shading will denote the audio volumes in between. FIG. 11B is again a key to mapping these shading assignments to numeric values, where 0 is white and 1 is black, and values in between 0 and 1 are shades of gray.

The position of the observer is projected onto the Audio Map bitmap 1110 represented by line 1112. Where this projected line intersects the bitmap 1110 will (if the line is within the bounds of this bitmap) be the observer's nearest pixel 1113.

The position of the observer is also projected onto the Audio Map bitmap 1120 represented by line 1122. Where this projected line intersects the bitmap 1120 will (if the line is within the bounds of this bitmap) be the observer's nearest pixel 1123.

This projection may be accomplished with the projection of a point

q=(x,y,z)

onto a plane given by a point

p=(a,b,c)

and a normal

n=(d,e,f)

which is

q_proj=q−dot(q−p,n)*n

This calculation assumes that n is a unit vector. [For more information about projection computations, see: <http://stackoverflow.com/questions/8942950/how-do-i-find-the-orthogonal-projection-of-a-point-onto-a-plane>.] Other methods of determining this projection are well known in the fields of geometry and mathematics. It may also be accomplished using Raycasting techniques and framework functions, such as in the API of the Unity game engine [see <http://docs.unity3d.com/Documentation/ScriptReference/Physics.Raycast.html>].

The numeric value of pixel 1113 and the numeric value of pixel 1123 are combined, and the result is then passed along to the audio transfer function. Note there are many possibilities for combining the numeric values of pixels 1113 and 1123.

One such possible algorithm for combining the numeric values of these pixels is a weighted average, computed as follows:

$${D}_{t} = {D}_{1} + {D}_{2}$$

$${R}_{F} = ( 1 - \frac{{D}_{1}}{{D}_{t}} ) \times A + ( 1 - \frac{{D}_{2}}{{D}_{t}} ) \times B$$

where:
D₁ is the length of the projection line 1112 to the first Audio Map;
D₂ is the length of the projection line 1122 to the second Audio Map;
Dₜ is the total length the two projection lines 1112 and 1122;
A is the numeric value associated with the observer's pixel 1113 in the first map 1110;
B is the numeric value associated with the observer's pixel 1123 in the second map 1120; and
R_{F} is the average of A and B weighted by the distance from user 1101 to each of the two projected pixels 1113 and 1123.

Other algorithms may be used to synthesize the numeric values of the pixel maps, such as:

R_{F}=A×B

or

R_{F}=\sqrt{A²+B²}.

Audio Maps may be static maps, but may also be animated bitmaps (e.g. pre-recorded or streamed movies, updated locally or from web, or modified ‘in situ’).

FIG. 13 illustrates an example in which the Audio Map is aligned in a manner such that the position of the observer 1101 is projected by line 1112 onto a map 1111 similar to the map 1100 of FIG. 11A, except that the map has been rotated. There is therefore no pixel in rotated map 1111 that corresponds to the observer's position, and therefore:

R_{F}=default value(as defined in code).

### II. Multi-Sampling

Because the extent in the virtual environment of a virtual character or observer may comprise a non-zero spatial volume (i.e. be larger than a single-dimensional point), Audio Zones may take the spatial volume of the observer into account. For example, the observer may be projected onto the Audio Zone's Audio Map (creating a ‘silhouette’) which may be sampled at its bounds or across its area to create a weighted average (for a single value result), or the audio transfer function may be applied to different parts of the Observer Object. For example (but not limited to): an observer's virtual head might sample an Audio Map for both right and left audio channels, corresponding to left and right virtual ears.

In some embodiments, sampling a single pixel on the Audio Map will give a scalar result for the numeric value. However, the Audio Map may be sampled at more pixels around the Observer's pixel, and computations may be performed on these pixels to derive more information about the Audio Zone. For example, in some embodiments, algorithms that make use of sampling the eight neighboring pixels around the observer's pixel may be used.

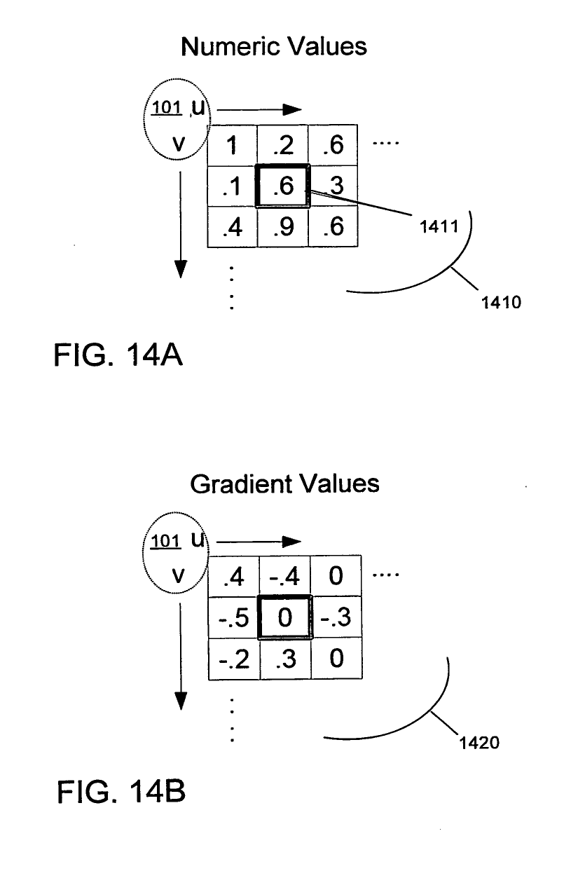

FIG. 14 illustrates the derivation of such a gradient using such an algorithm. As illustrated in FIG. 14A, a portion of a bitmap 1410 is shown, with the observer's pixel value 1411 at the center, along with various numeric values shown in the cells for the neighboring pixels. In FIG. 14B, a table of the corresponding gradient values 1420 is shown, obtained at each cell by subtracting numeric value of the observer's pixel from the neighboring cell's numeric value. Subtracting the value of one pixel from the one to the left of it, for instance, will yield a horizontal differential, or gradient; and subtracting a pixel from the one above it will yield a vertical gradient.

Therefore, if the property is ‘desirable’, the gradient of ‘desire’ may be determined, and a suggestion may be made to the player to move the character under his control in the direction of ‘more desirable’, for instance, by choosing the direction of the derived gradient pixel value that is the greatest. Likewise, if the property is ‘danger’, the gradient of ‘danger’ may be determined, and a suggestion may be made to the player to move the character under his control in the direction of ‘less danger’, for instance, by choosing the direction of the derived gradient pixel value which is leads to the greatest reduction.

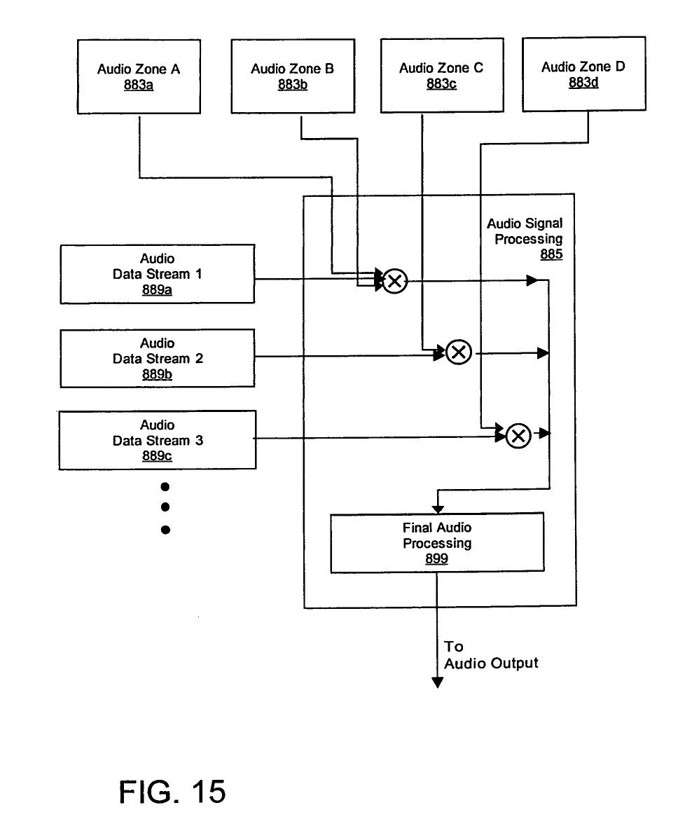

FIG. 15 illustrates that in some embodiments, multiple Audio Zones 883a, 883b, 883c, 883d, . . . may be used and mixed to provide the audio signals for the same scene when the Audio Zones overlap. The audio data streams 889 they control may be the same or different; for example, in FIG. 15, Audio Zone A 883a and Audio Zone B 883b both provide Audio Transfer Functions that may influence the data provided by Audio Stream 1 889a. The programming of the Audio Signal Processing step 885 will determine the exact algorithm used to mix and merge these multiple inputs. However, also in FIG. 15, Audio Zone C 883c is shown to only influence Audio Data Stream 2 889b. Likewise, Audio Zone D 883d is shown to only influence Audio Data Stream 3 889c. The observer's position was presented to all Audio Zones in a previous step 815, and their resulting properties presented to the audio signal processor are, in some embodiments, all presented to the audio signal processing step for mixing and processing.

In some embodiments, using more than one Audio Zone would be useful in cases where four bitmap channels (as in an RGBA bitmap) are not enough to fully describe the properties. For example, the R,G,B channels of two separate Audio Maps may be used to represent loudness, delay, distortion for one bitmap; and echo, low-pass filtering, and distortion for the other bitmap. Thus two Audio Zones are sampled, and their resulting values R are applied to the transfer function.

In some embodiments, virtual coordinates that fall between Audio Zones (that is, points which do not lie within the bounds of any one Zone Object) may infer property values from surrounding Audio Zones by interpolating values between the Audio Maps on Zone Objects within those zones, creating an Audio Meta-Zone.

In some embodiments, Position, Size, and Rotation may be changed. The coordinates governed by an Audio Zone (including their Audio Map(s)) may be changed by translation within the virtual 3D space, made larger or smaller, and/or rotated, all in real time. These changes may be in response to input from the player, or due to other conditions that change within the programming environment of the game. These changes may affect which pixels of the bitmap are sampled.

For the purposes of this Application, a ‘static bitmap’ will be understood to mean a bitmap that does not change. For the purposes of this Application, ‘dynamic bitmap’ will be understood to mean a bitmap that does change over time, as an animation or movie or modified by computer algorithm.

Note that, although FIGS. 8, 9, 10 and 15 illustrate particular steps carried out in a particular order, the order for some embodiments may be different, and those skilled in the art may recognize that steps may be carried out in other orders and sequences from those shown here. Likewise, although some embodiments may mix data from all available audio streams, some embodiments will select or limit the number and properties of the various audio streams.

Single-bitmap Audio Maps generally represent two spatial dimensions, but in some embodiments, several Audio Maps may be used in conjunction to cover three-dimensional volumes. Thus a property may change, not only as the observer moves horizontally, but vertically as well.

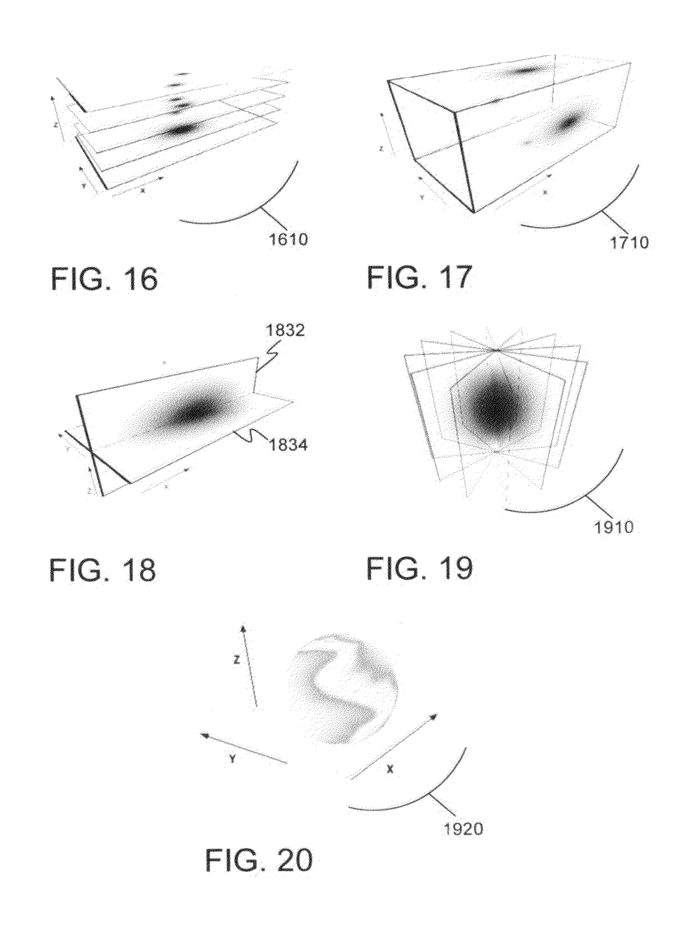

FIGS. 16-20 illustrate several possible arrangements of Audio Maps, which are a representation of methods for spatialized control of audio in accordance with the embodiments of the present invention.

One such arrangement is depicted in FIG. 16. A collection of Audio Maps 1610 are ‘stacked’ parallel to each other, and the nearest bitmaps to an observer's position are sampled and the final value for R_{F} may be a weighted average. Note that simple linear interpolation would require only the two nearest Audio Maps, but higher-order interpolations can take account of more of nearby Audio Maps as well.

Another such arrangement is depicted in FIG. 17. Four Audio Maps 1710 are placed orthogonal to each other in a ‘box’ configuration, formed by placing Audio Maps on four opposing surfaces (rectangular Audio Zone Objects). The final value for R_{F} may be based on sampling all four Audio Maps, finding a weighted average of the pixel on each Audio Map that is nearest to the Observer Object.

Another such arrangement is depicted in FIG. 18. Two Audio Maps 1832 and 1834 are used, placed perpendicular to each other. In some embodiments, they are both sampled, as was illustrated in FIG. 12, and the two resulting values are averaged (weighted by distance from the actual point corresponding to the observer). Thus the value changes as the observer not only moves about the ground, but as the observer changes altitude as well.

Another such arrangement is depicted in FIG. 19. A radial arrangement 1910 of Audio Maps is used. The final value for R_{F} may be computed by finding, for example, the pixels on the nearest two (or more) Audio Maps and interpolating those values.

Another such arrangement is depicted in FIG. 20. A parametric three-dimensional Zone Object 1920 (in this illustration, a sphere) is covered by an Audio Map. Any point inside the sphere can be associated with a weighted average of the surrounding Audio Map values based on interpolation, and points outside the sphere may take on extrapolated values. Arbitrary parametric shapes are allowed, including but not limited to ellipsoids, cylinders, toroids, cones, etc. FIG. 4 depicts a multi-layer bitmap that can be used as a three-dimensional Audio Zone Object using volumetric bitmaps. A ‘volumetric bitmap’ will be understood to mean a bitmap that describes a volume of space, rather than a plane, as seen in medical imaging, for example.

Other arbitrary arrangements of Audio Maps may be used to cover the space, where a weighted average may be computed, and will be known to those skilled in the art.

### III. An Implementation Example

### Zombies

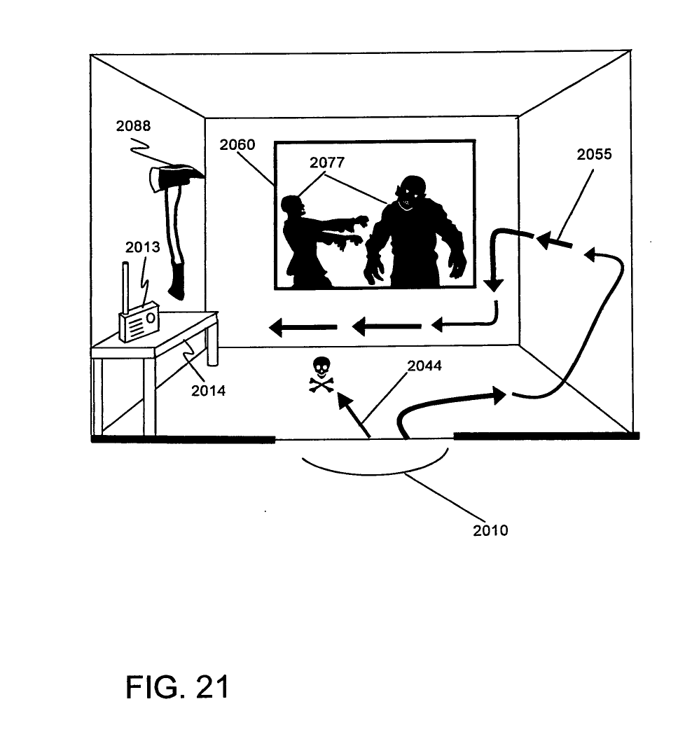

To better illustrate the utility of the invention, a more detailed illustration of a possible implementation within a computer game may be instructive. This example refers to the drawings of FIGS. 21-25.

Assume that a computer game set in a zombie apocalypse, and assume the player must control a character within the game to avoid or destroy virtual zombies; if the zombies come in close proximity, they will grab at the virtual character and, if they succeed in grabbing the character, will proceed to eat his virtual flesh, ending the virtual life of the character.

Assume also that the zombies emit a groan or other audio signal as they shuffle about, and that one of the rules of the game is that, if the player hears a zombie groan more than a certain volume (which a player will quickly learn to recognize through experience), it indicates that the zombies can detect the virtual character, and can therefore come to attack.

Referring now to FIG. 21, assume that you, the player, are guiding a virtual character in a virtual building, and are preparing to enter a room as depicted in FIG. 21 through an entry 2010. On the left, a radio 2013 stands on a table 2014, and is broadcasting an audio message that provides information about how to proceed if encountering zombies, which you (the player) hear through audio headphones or some other audio channel. Beyond the table 2014 on the left, in the far corner of the room, a weapon 2088 is hanging on the wall that, as the audio stream from the radio 2013 informs you, would be very useful against zombies.

However, at the far end of the room is an open window 2060. If the player directs the virtual character to walk directly to the weapon 2088 using a direct path 2044, the sound of zombies 2077 groaning outside will increase the closer the character gets to the virtual window 2060. If the player directs the character to proceed anyway and simply rush to the weapon along the direct path 2044, virtual zombies 2077 will pour through the window 2060 and devour the character (virtually).

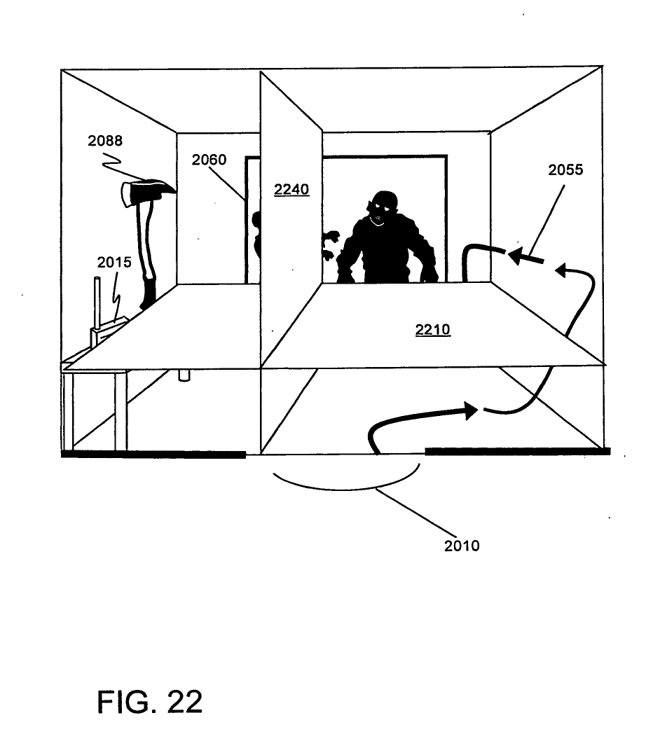

FIGS. 22 through 25 illustrate the use of Audio Zone Maps corresponding to the situation of FIG. 21.

In FIG. 22, the drawing of FIG. 21 is reproduced, but with two planes, one horizontal plane 2210 and one vertical plane 2240, identified. These planes will represent the planes in which Bitmaps that control audio loudness for this scene will be defined.

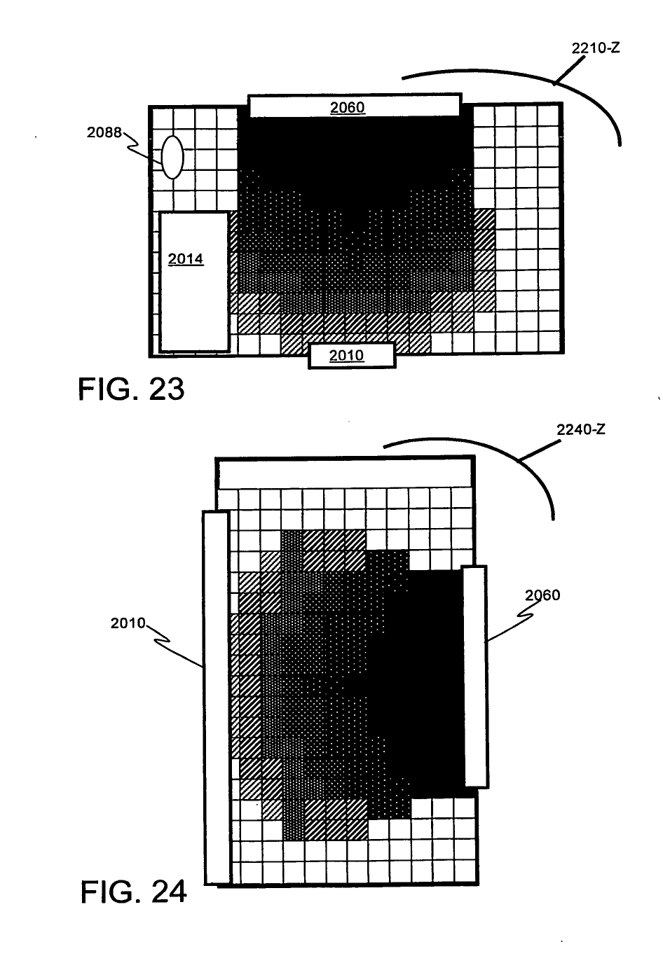

In FIG. 23, the Audio Map 2210-Z (corresponding to the horizontal plane 2210) governing the groans corresponding to zombies 2077 outside the window 2060 is shown. Pixels illustrated with dark shading represent loud sounds; pixels with no shading (white pixels) represent silence. From the illustration, it is clear that the zombie sounds will be loud almost anywhere in front of the window 2060, except at the entry 2010. However, relative quiet (and therefore safety for the virtual character) can be found along the right hand wall.

In FIG. 24, the Audio Map 2240-Z (corresponding to the vertical plane 2240) governing the groans corresponding to zombies 2077 outside the window 2060 is shown. Pixels illustrated with dark shading represent loud sounds; pixels with no shading (white pixels) represent silence. From the illustration, it is clear that zombie sounds will be loud almost anywhere in front of the window 2060, except at the entry 2010. However, relative quiet (and therefore safety for the virtual character) can be found just below the window 2060.

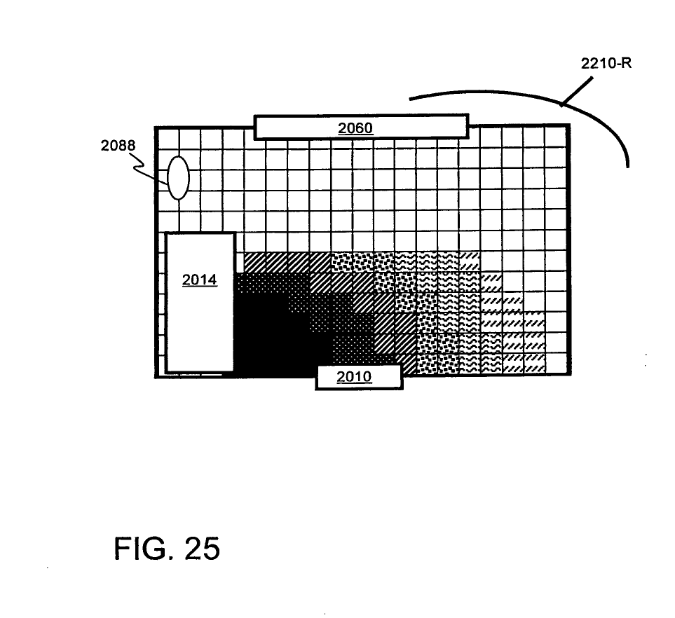

In FIG. 25, the Audio Map 2210-R (corresponding again to the horizontal plane 2210) governing the sound of the audio stream from the virtual radio 2013 is shown. Pixels illustrated with dark shading represent loud sounds; pixels with no shading (white pixels) represent silence. From the illustration, it is clear that the radio audio stream can only be heard when the character is standing in the entry 2010.

Returning to FIG. 21, astute players will realize that there is a solution to the problem. The path to take 2055 comprises entering the room through the entry 2010 and moving to the right side of the room, walking along the right hand wall, and then ducking under the window 2060 to approach the weapon 2088. The audio volume the player hears corresponding to the groans outside will be the player's guide to direct the character to stop or proceed; by hugging the wall and keeping low, the volume of the zombie groans indicates whether the character is still virtually “safe”.

The audio message from the virtual radio 2013 may also reiterate this message, but the audio stream of the virtual radio may be set so that the player can no longer hear this message at the far side of the room, as is illustrated in FIG. 25. The information about how to proceed must therefore be heard and learned before proceeding into the room.

For the combination of the audio signals, a weighted combination or any of the other algorithms previously discussed can be used.

All of this rather complex audio instruction can be created by the creation of the reference bitmaps as illustrated in FIGS. 23-25, with no need to write code for complex audio modeling or involved programming. In fact, with a suitable graphical painting program, designs such as those shown in FIGS. 23-25 can be created in minutes, and then used as reference files to guide the creation of very complex audio environments.

### IV. A Second Implementation Example

### The Yellow Brick Road

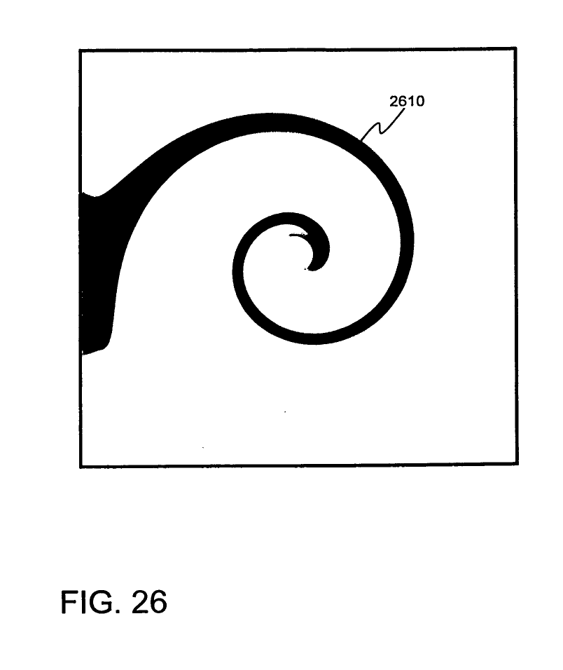

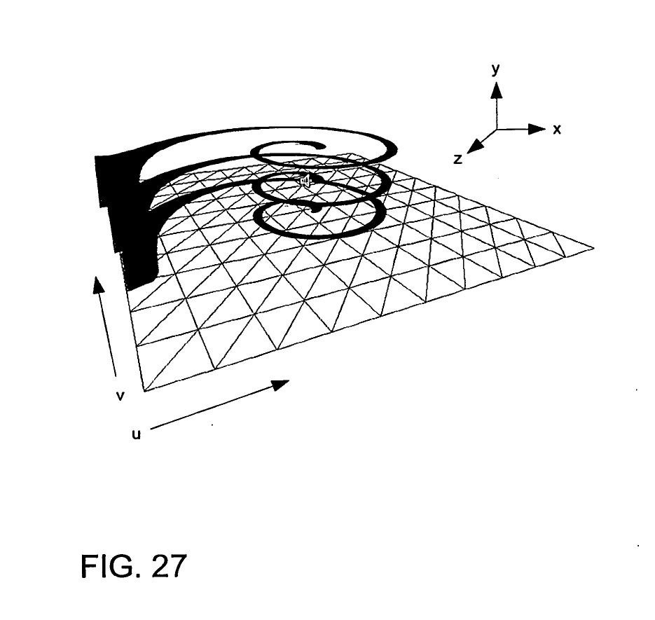

Another example of an implementation of the invention is shown in FIGS. 26 and 27. In FIG. 26, a graphical spiral pattern 2610 is shown. The bitmap representing this graphic figure is a 512×512 (u x v) pixel bitmap, and was created on a simple Windows-based laptop and was created using the software program PaintShop Pro [originally developed by JASC Inc, and now distributed by Corel Corporation of Ottawa, Ontario, Canada].

The bitmap was produced in seconds by creating a single dark line, and then “twirling” it into a spiral using one of the many standard graphics manipulation subroutines available within PaintShop Pro.

Although stored as an RGBA bitmap, the dark/light information visible in the graphic is only stored in the “A” channel of the bitmap.

This bitmap has been built into an audio demonstration program, such as those presented in the Appendices, so that when the character's coordinates (x,y) match the aligned coordinates (u,v) in which the “A” channel has a non-zero value (e.g. when matched with the spiral in the bitmap, an audio channel is turned on to play pre-recorded audio stream through the audio output. The graphic presentation in the demo version presents the “path” as a yellow marking on the ground, and the audio stream is a recording from the Wizard of Oz, so that it appears that the listener hears “Follow the Yellow Brick Road” when the character is standing on the path—and only when standing on the path.

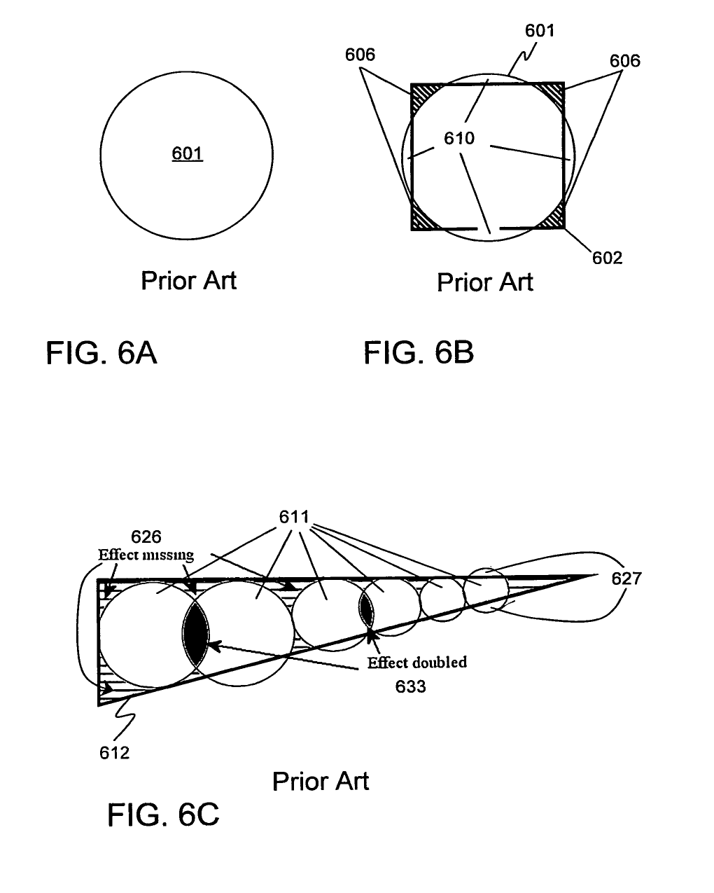

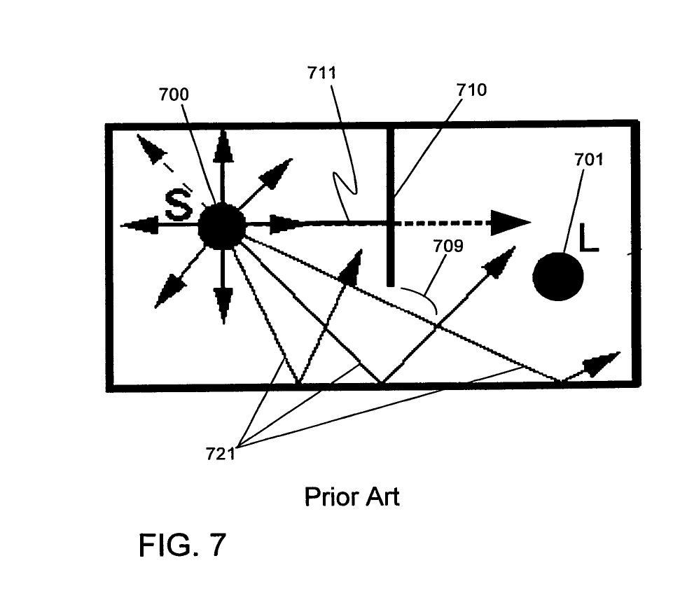

Creating such a spiral audio source from scratch is a far more difficult task. Audio placement tools do exist in software environments such as the Unity game development environment to systematically place audio sources with certain properties and characteristics in a scene with a drag-and-drop approach. However, to create a spiral with the parametric precision seen in FIG. 26, many small sound sources would need to be placed in a spiral path, with volume balances empirically to minimize the undesirable audio interference effects, as were discussed in the prior art example of FIG. 6.

Crafting such an Audio Map with this prior art technology takes at least 30 minutes or more—30 to 60 times longer than the method of the present invention. And, there is no guarantee that the prior art techniques will produce audio quality of anything like that achievable with the present invention.

To eliminate the problems with audio uniformity, the designer could write specialized code to parameterize such a spiral, and then generate audio when the parametric conditions were met by the player's character's virtual position. This could in principle produce a precise audio environment, as desired. However, coding this direct solution will not take minutes, but hours of work and debugging, and the result would be a custom audio environment, for only one particular scene.

FIG. 27 illustrates a unique improvement unavailable to any of the prior art techniques.

Using multiple copies of the Audio Map that was illustrated in FIG. 26, multiple bitmaps can be placed at different elevations, as was illustrated in FIGS. 4 and 16. Now, as the virtual character walks along the “yellow brick road”, depending on the programming instructions, the audio track may only play the audio stream when the character's head is at a set number of elevations (in FIG. 27, three elevations are shown). If the character's head is in the upper spiral, the song is heard. If the head is then lowered, the sound can be extinguished until reaching the lower spirals.

To the inventor's current knowledge, this kind of synthetic auditory management is unavailable in any other game design software.

### V. Implementation by Computer

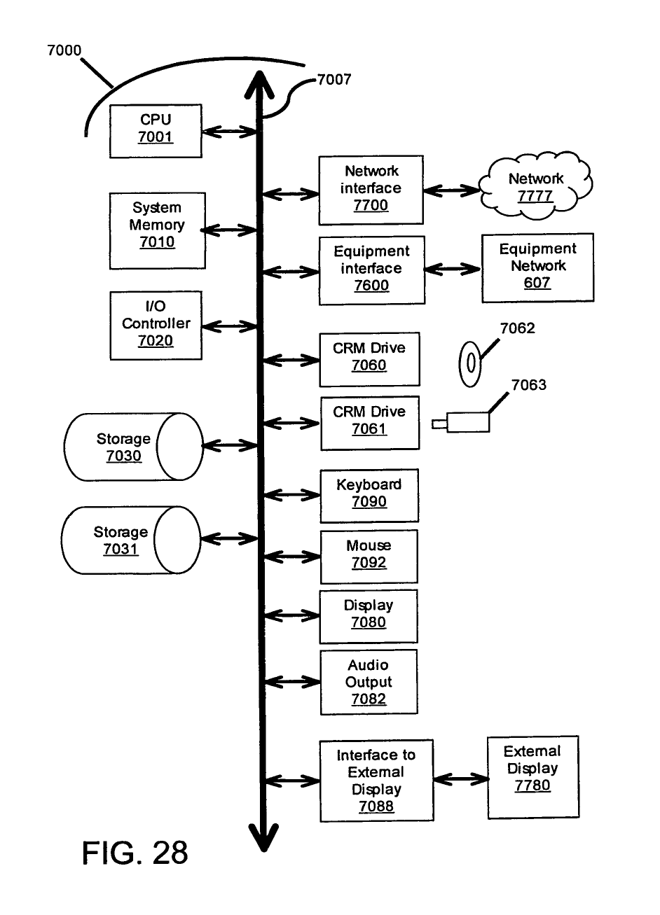

FIG. 28 illustrates a block diagram of an exemplary computer system that can serve as a platform for portions of embodiments of the present invention. Computer code in programming languages such as, but not limited to, C, C++, C#, Java®, Javascript®, Objective C®, Boo, Lua, assembly, Fortran, APL, etc., and executed in operating environments such as Windows® and all its variants, Mac OS-X®, iOS®, Android®, Blackberry®, UNIX®, Linux®, etc., can be written and compiled into a set of computer or machine readable instructions that, when executed by a suitable computer or other microprocessor based machine, can cause the system to execute the method of the invention.

Such a computer system 7000, can comprise a bus 7007 which interconnects major subsystems of computer system 7000, such as a central processing unit (CPU) 7001, a system memory 7010 (typically random-access memory (RAM), but which may also include read-only memory (ROM), flash RAM, or the like), an input/output (I/O) controller 7020, one or more data storage systems 7030, 7031 such as an internal hard disk drive or an internal flash drive or the like, a network interface 7700 to an external network 7777, such as the Internet, a fiber channel network, or the like, an equipment interface 7600 to connect the computer system 7000 to a network 607 of other electronic equipment components, and one or more drives 7060, 7061 operative to receive computer-readable media (CRM) such as an optical disk 7062, compact disc read-only memory (CD-ROM), compact discs (CDs), floppy disks, universal serial bus (USB) thumbdrives 7063, magnetic tapes and the like. The computer system 7000 may also comprise a keyboard 7090, a mouse 7092, and one or more various other I/O devices such as a trackball, an input tablet, a touchscreen device, an audio microphone and the like. The computer system 7000 may also comprise a display device 7080, such as a cathode-ray tube (CRT) screen, a flat panel display or other display device; and an audio output device 7082, such as a speaker system. The computer system 7000 may also comprise an interface 7088 to an external display 7780, which may have additional means for audio, video, or other graphical display capabilities for remote viewing or analysis of results at an additional location.

Bus 7007 allows data communication between central processor 7000 and system memory 7010, which may comprise read-only memory (ROM) or flash memory, as well as random access memory (RAM), as previously noted. The RAM is generally the main memory into which the operating system and application programs are loaded. The ROM or flash memory can contain, among other code, the basic input/output system (BIOS) that controls basic hardware operation such as the interaction with peripheral components. Applications resident with computer system 7000 are generally stored on storage units 7030, 7031 comprising computer readable media (CRM) such as a hard disk drive (e.g., fixed disk) or flash drives.

Data can be imported into the computer system 7000 or exported from the computer system 7000 via drives that accommodate the insertion of portable computer readable media, such as an optical disk 7062, a USB thumbdrive 7063, and the like. Additionally, applications and data can be in the form of electronic signals modulated in accordance with the application and data communication technology when accessed from a network 7777 via network interface 7700. The network interface 7700 may provide a direct connection to a remote server via a direct network link to the Internet via an Internet PoP (Point of Presence). The network interface 7700 may also provide such a connection using wireless techniques, including a digital cellular telephone connection, a Cellular Digital Packet Data (CDPD) connection, a digital satellite data connection or the like.

Many other devices or subsystems (not shown) may be connected in a similar manner (e.g., document scanners, digital cameras and so on). Conversely, all of the devices shown in FIG. 28 need not be present to practice the present disclosure. In some embodiments, the devices and subsystems can be interconnected in different ways from that illustrated in FIG. 28. The operation of a computer system 7000 such as that shown in FIG. 28 is readily known in the art and is not discussed in further detail in this Application.

Code to implement the present disclosure can be stored on computer-readable storage media such as one or more of: the system memory 7010, internal storage units 7030 and 7031, an optical disk 7062, a USB thumbdrive 7063, one or more floppy disks, or on other storage media. The operating system provided for computer system 7000 may be any one of a number of operating systems, such as MS-DOS®, MS-WINDOWS®, UNIX®, Linux®, OS-X® or another known operating system.

Moreover, regarding the signals described herein, those skilled in the art will recognize that a signal can be directly transmitted from one block to another, between single blocks or multiple blocks, or can be modified (e.g., amplified, attenuated, delayed, latched, buffered, inverted, filtered, or otherwise modified) by one or more of the blocks. Furthermore, the computer as described above may be constructed as any one of, or combination of, computer architectures, such as a tower, a desktop, a laptop, a workstation, or a mainframe (server) computer. The computer system may also be any one of a number of other portable computers or microprocessor based devices such as a mobile phone, a smart phone, a tablet computer, an iPad®, an e-reader, or wearable computers such as smart watches, intelligent eyewear and the like.

The computer system may also be one of several microprocessor-based game consoles, such as the Xbox®, Xbox 360®, and Xbox One® manufactured by Microsoft Corp. of Redmond, Wash.; the GameCube™, Wii™, Wii™, GameBoy™, DS™, 3DS™, DSi™, etc. from Nintendo Co. Ltd. of Kyoto, Japan; the Playstation®, Playstation® 2, Playstation® 3, and Playstation® 4, PSP™, etc. manufactured by Sony Corp. of Tokyo, Japan; and the OUYA console running the Android™ operating system and manufactured by OUYA Inc. of Santa Monica, Calif.

The computer system may also be one or more of the embedded computers found in appliances, toys, robots, medical devices and systems, automobiles, aircraft, flight simulators, and other configurations that will be known to those skilled in the art.

### VI. Alternative Embodiments

In some embodiments, the bitmap is created algorithmically by pre-computing spatial acoustic numeric values and storing them as pixels in a bitmap. This may be called ‘Audio Baking’.

In some embodiments, the bitmap is created by photography, videography, or other image-capture techniques.

In some embodiments, the bitmap is created by sampling real-world data in a geographic area (such as temperature, or radio frequency intensities, for example), and the numeric values associated with those sensors are stored as pixels in a bitmap.

In some embodiments, several bitmaps are arranged parallel to one another. Each bitmap represents a ‘slice’ of the scene at, for example, a different altitude. The bitmap closest to the observer, as well as bitmaps to either side of that bitmap, may also be sampled, and their numeric values interpolated to provide the value that will represent the associated property, for example, loudness.

In some embodiments, a single bitmap comprises tiles, where each tile is a ‘slice’ of the scene at a different coordinate (altitude, or Y value, or longitude or latitude, for example). Tiles are chosen which are closest to the observer, as well as ones on either side of it, may be sampled, and their numeric values interpolated to provide the value that will represent the associated property, for example, loudness.

In some embodiments, several bitmaps are arranged radially. Each bitmap represents a ‘slice’ of the scene at a different angle through a line in the scene. The bitmap closest to the observer, as well as ones on either side of it, may be sampled, and their numeric values interpolated to provide the value that will represent the associated property, for example, loudness.

In some embodiments, several bitmaps are arranged on the surface of a polyhedron, such as a rectangular box or a polyhedral mesh. Each bitmap represents a ‘slice’ of space through which that bitmap's plane passes. The bitmaps closest to the observer, as well as other nearby bitmaps, may be sampled, and their numeric values interpolated to provide the value that will represent the associated property, for example, loudness.

In some embodiments, one or more bitmaps comprise a look-up table (e.g. a palette) through which the final pixel value is determined.

In some embodiments, one or more bitmaps are implemented as mipmaps. For purposes of this Application, a ‘mipmap’ or ‘mipmaps’ will be understood to mean a bitmap which contains within itself alternate representations of itself at different resolutions, or a data structure containing or referencing a collection of bitmaps which are alternate representations of itself at different resolutions. [For more on mipmaps, see Lance Williams, “Pyramidal Parametrics”, Computer Graphics, Vol. 17, pp. 1-11 (July 1983); and <http://en.wikipedia.org/wiki/Mipmap>.]

In some embodiments, each channel of a multi-channel bitmap represents different properties. For example, the red channel may represent the loudness, the green channel may represent reverberation, and the blue channel may represent a coefficient for low-pass filtering of the sound.

In some embodiments, a multi-channel bitmap (containing, for example, red/green/blue channels) is first processed to change its color space to another color space (such as hue/saturation/value, for example), and the resulting numeric values in that alternate color space are used as the numeric values to set the property.

In some embodiments, the indicated pixel's numeric value is not necessarily interpolated, but corresponds to a discreet property. For example, each color may indicate a different audio stream that should be sent to the audio signal processor. As another example, each color corresponds to behavioral commands for other aspects of the simulation (such as the orders for a programmatic object (such as computer-controlled game opponent)) that should set the condition of, for example, a current mode of operation (e.g. attack, fight, flee, idle, die, etc.).

In some embodiments, the bitmap(s) used are dynamic in nature, as in pre-recorded or live video streams, or algorithmically generated in real-time.

In some embodiments, not just one pixel, but several pixels within the area of the virtual character or observer are sampled, and their numeric values mathematically combined using a predetermined algorithm to reach the final result to send to the audio signal processor.

In some embodiments, in addition to the pixel closest to the user, pixels around that pixel are also sampled, and a gradient, or derivative, is computed by subtracting the adjacent pixel's numeric values. The difference is then used as the sample numeric value to send to the audio signal processor, for example.

In some embodiments, multiple bitmaps are employed. The different bitmaps provide additional channels for one or more properties. For example, if 3-channel bitmaps (red/green/blue) are insufficient to describe a property, additional bitmaps may be used in similar arrangement, such as to provide additional red/green/blue channels.

In some embodiments, multiple bitmaps are employed. The different bitmaps may cover various spatial areas of the scene. Thus a 3-dimensional space may be filled with an arbitrary number and arrangements of bitmaps, to create arbitrarily complex regions of space that will affect the property.

Additional embodiments that also pertain to other properties in scenes, such as lighting and shadows, physics, haptics and tactile rendering, real-world performance effects, and control of other aspects of the simulated environment, such as computer-controlled characters and other aspects of game play, may be known to those skilled in the art.

Although properties of sound and audio rendering are used throughout this application, it is intended that they are only one possible application of this invention. Other renderings may include, but not be limited to: lighting and shadows, physics, haptics and tactile feedback, control of computer-controlled characters, real-world effects (such as, but not limited to: fog, heating/cooling, wind, scents, motion control, fluid flows, etc.) and the like.

### VII. Code Listings in Appendices

Two examples of embodiments of the invention in machine-executable C# code are attached in Appendix A and Appendix B following the text of the Specification.

### VII.A: Appendix A

### Loudness Control Code Embodiment Example

Following the text of this Specification in Appendix A is a listing of an example of an embodiment of the invention written in program code, in this case in the C# language, and designed for use in the Unity game development tool. The Unity game development environment compiles code that runs on Windows, Macintosh, and Unix computers, web browser code, Android, iOS, Blackberry and Windows Phone platforms.

For the embodiment illustrated in Appendix A, an RGBA (4-channel) bitmap is sampled, one of those channels is chosen for its numeric value, and that value is used as the volume control for the associated audio stream.

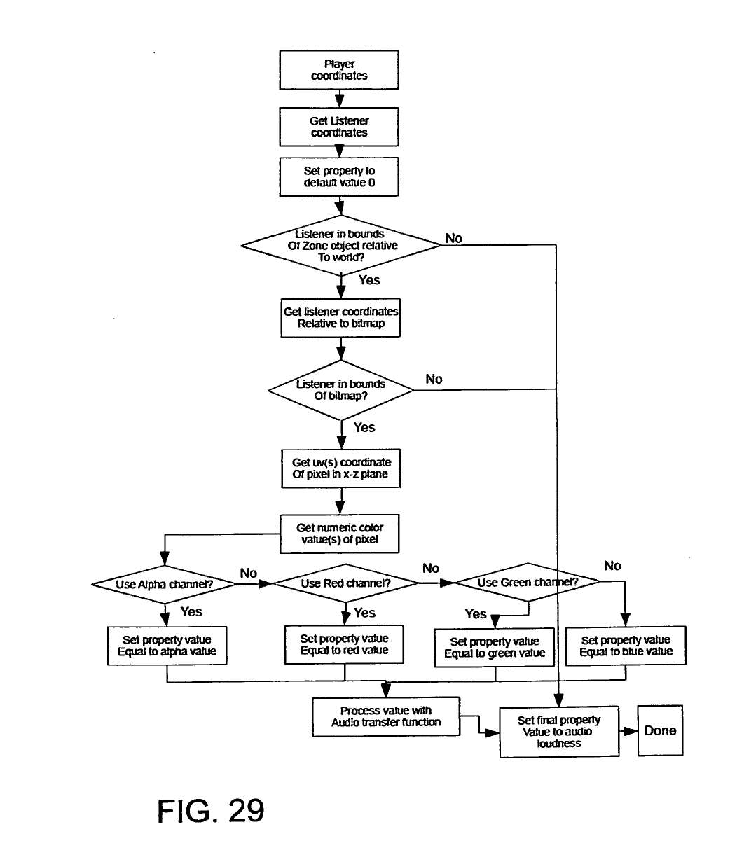

A flow chart for the embodiment presented in the code of Appendix A is shown in FIG. 29.

### VII.B: Appendix B

### Stream Selection Code Embodiment Example

Following the text of this Specification in Appendix B is a listing of an example of an embodiment of the invention written in program code, in this case in the C# language, and designed for use in the Unity game development tool. The Unity game development environment compiles code that runs on Windows, Macintosh, and Unix computers, web browser code, Android, iOS, Blackberry and Windows Phone platforms.

For the embodiment illustrated in Appendix B, an RGBA (4-channel) bitmap is sampled, one of those channels is chosen for its numeric value, and that value is used to choose between three different audio streams.

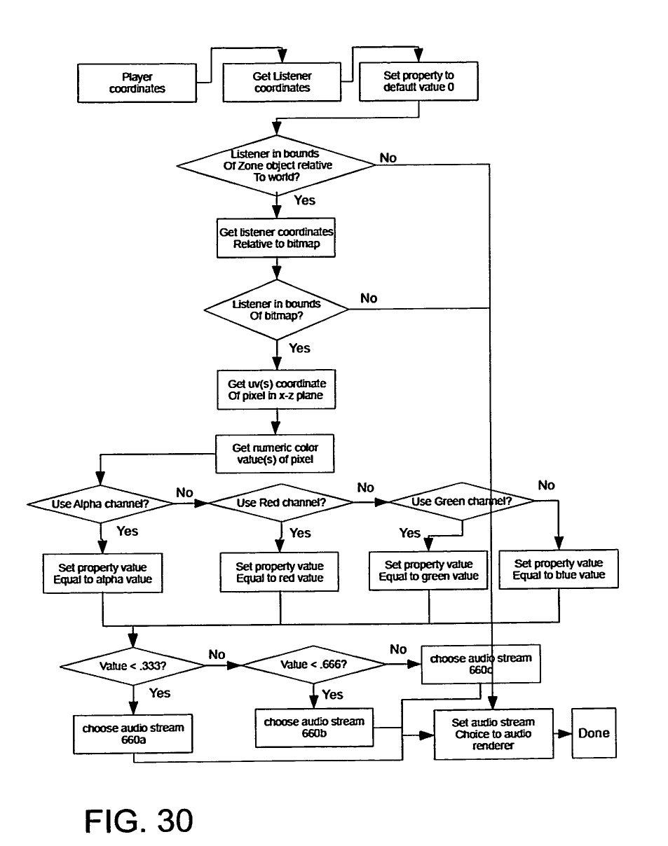

A flow chart for the embodiment presented in the code of Appendix B is shown in FIG. 30.

### VIII. Additional Limitations

With this Application, several embodiments of the invention, including the best mode contemplated by the inventor, have been disclosed. It will be recognized that, while specific embodiments may be presented, elements discussed in detail only for some embodiments may also be applied to others.

While specific embodiments, materials, designs, configurations, formats, variables, logical relationships and sequences of steps have been set forth to describe this invention and the preferred embodiments, such descriptions are not intended to be limiting. Modifications and changes may be apparent to those skilled in the art, and it is intended that this invention be limited only by the scope of the appended claims.

APPENDIX A
Loudness Control Code Embodiment Example.

```
// This code is called periodically, for example, on each video frame rendering.
// It has available to it the current player position and access to the AudioZone structure
// which refers to the AudioMap bitmap:
// if listener is inside the rough bounding box of the AudioZone...
Vector3 listenerPosition = currentPlayerPosition;
float v = 0.0f; // initialize the property to zero
if (audioZone.Contains (listenerPosition))
{
        // get listener in local (bitmap) coordinates (accounts for scale and rotation)
        Vector3 listenerRelative = audioZone.InverseTransformPoint(listenerPosition);
        // if listener is inside the actual bounds of the bitmap (true if x,y,z are in (−.5, .5) )
        if (Mathf.Abs(listenerRelative.x) < .5f &&
                Mathf.Abs(listenerRelative.y) < .5f &&
                Mathf.Abs(listenerRelative.z) < .5f)
        {
                // get bitmap value at this point
                Vector3 uvw = listenerRelative - Vector3(.5, .5, .5); // uvw is in (−.5,.5)
                uvw.x *= audioMap.width; // compute the column/row (x,y) of the pixel
                uvw.z *= audioMap.height;
                // extract the pixel
                Color c = audioMap.GetPixel ((int)(audioMap.width−uvw.x), (int)(audioMap.height−uvw.z));
                // Optionally choose a channel from the color structure containing the desired value
                switch (patchFrom)
                {
                        case PatchFrom.Alpha:
                                v = c.a;
                                break;
                        case PatchFrom.Red:
                                v = c.r;
                                break;
                        case PatchFrom.Green:
                                v = c.g;
                                break;
                        case PatchFrom.Blue:
                                v = c.b;
                                break;
                }
                // optional audio transfer function
                v = 1 − v; // indicates that ‘darker’ is ‘louder’
        }
}
// set volume from value in the channel from the color of the chosen pixel
audio.volume = v;
}
```

APPENDIX B
Stream Selection Code Embodiment Example.

```
// This code is called periodically, for example, on each video frame rendering.
// It has available to it the current player position and access to the AudioZone structure
// which refers to the AudioMap bitmap:
// if listener is inside the rough bounding box of the AudioZone...
Vector3 listenerPosition = currentPlayerPosition;
float v = 0.0f; // initialize the property to zero
if (audioZone.Contains (listenerPosition))
{
        // get listener in local (bitmap) coordinates (accounts for scale and rotation)
        Vector3 listenerRelative = audioZone.InverseTransformPoint(listenerPosition);
        // if listener is inside the actual bounds of the bitmap (true if x,y,z are in (−.5, .5) )
        if (Mathf.Abs(listenerRelative.x) < .5f &&
                Mathf.Abs(listenerRelative.y) < .5f &&
                Mathf.Abs(listenerRelative.z) < .5f)
        {
                // get bitmap value at this point
                Vector3 uvw = listenerRelative - Vector3(.5, .5, .5); // uvw is in (−.5,.5)
                uvw.x *= audioMap.width; // compute the column/row (x,y) of the pixel
                uvw.z *= audioMap.height;
                // extract the pixel
                Color c = audioMap.GetPixel ((int)(audioMap.width−uvw.x), (int)(audioMap.height−uvw.z));
                // Optionally choose a channel from the color structure containing the desired value
                switch (patchFrom)
                {
                        case PatchFrom.Alpha:
                                v = c.a;
                                break;
                        case PatchFrom.Red:
                                v = c.r;
                                break;
                        case PatchFrom.Green:
                                v = c.g;
                                break;
                        case PatchFrom.Blue:
                                v = c.b;
                                break;
                }
        }
}
// optional audio transfer function
// select an audio stream depending on ‘v’
if (v < .333)
        audio.clip = clip660a;
else if (v < .666)
        audio.clip = clip660b;
else
        audio.clip = clip660c;
}
```

What is claimed is:

1. A computer implemented method for managing audio signal properties, comprising the steps of:
identifying one or more audio signals to be controlled;
identifying a property of the one or more audio signals to be controlled;
reading data representing one or more numeric values from a digitally stored reference file;
calculating a setting for the property of the one or more audio signals based on the data representing one or more numeric values; and
electronically controlling the property of the one or more audio signal based on the calculated property setting.

2. The method of claim 1, in which
the digitally stored reference file is a bitmap.

3. The method of claim 1, in which
the property of the audio signal is the loudness.

4. The method of claim 1, in which
the property of the audio signal is the frequency spectrum.

5. The method of claim 1, in which
the property of the audio signal is selected from the group consisting of pitch, echo, delay, reverberation, phase, distortion, noise level, filtering profiles and Doppler amount.

6. The method of claim 1, in which
the step of identifying one or more audio signals to be controlled comprises identifying several audio signals to be controlled; and
in which the method
additionally comprises selecting a subset of the audio signals for further processing, in which
the selection of the subset of audio signals is also based on the data representing one or more numeric values.

7. The method of claim 1, additionally comprising the steps of:
reading additional data representing one or more numeric values from a second digitally stored reference file; and
calculating a setting for the property of the one or more audio signal based on the data representing one or more numeric values from the digitally stored reference file and
the additional data representing one or more numeric values from the second digitally stored reference file.

8. The method of claim 7, in which
the second digitally stored reference file is a bitmap.

9. The method of claim 7, in which
the property of the audio signal is the loudness.

10. A non-transitory computer readable medium for use in a computer system, the non-transitory computer readable medium having encoded upon it computer instructions executable by the computer system to perform process steps comprising:
identifying one or more audio signals to be controlled;
identifying a property of the one or more audio signals to be controlled;
reading data representing one or more numeric values from a digitally stored reference file;
calculating a setting for the property of the one or more audio signals based on the data representing one or more numeric values; and
electronically controlling the property of the one or more audio signal based on the calculated property setting.

11. The non-transitory computer readable medium of claim 10, in which
the digitally stored reference file is a bitmap.

12. The non-transitory computer readable medium of claim 10, in which
the property of the audio signal is the loudness.

13. The non-transitory computer readable medium of claim 10, in which
the property of the audio signal is the frequency spectrum.

14. The non-transitory computer readable medium of claim 10, in which
the property of the audio signal is selected from the group consisting of pitch, echo, delay, reverberation, phase, distortion, noise level, filtering profiles and Doppler amount.

15. A microprocessor implemented method for managing output properties from a system having one or more digitally simulated environments, comprising the steps of:
identifying one or more output signals to be controlled;
identifying a property of the one or more output signals to be controlled;
reading data representing one or more numeric values from a digitally stored reference file;
calculating a setting for the property of the one or more output signals based on the data representing one or more numeric values; and
electronically controlling the property of the one or more output signals based on the calculated property setting.

16. The method of claim 15, in which
the digitally stored reference file is a bitmap.

17. The method of claim 15, in which
the system having one or more digitally simulated environments is a video game.

18. The method of claim 15, in which
the system having one or more digitally simulated environments is a virtual reality system.

19. The method of claim 15, in which
the system having one or more digitally simulated environments is a flight simulator.

20. The method of claim 15, in which
the system having one or more digitally simulated environments is a robotic system.
